(19) United States
(12) Patent Application Publication
(10) Pub. No.: US 2026/0215098 A1
(43) Pub. Date: Jul. 23, 2026

(54) DISPLAY APPARATUS

(71) Applicant: Semiconductor Energy Laboratory Co., Ltd., Atsugi-shi (JP)

(72) Inventors: Shunpei YAMAZAKI, Setagaya (JP); Yasutaka NAKAZAWA, Tochigi (JP); Rai SATO, Tochigi (JP); Satoru IDOJIRI, Tochigi (JP); Kenichi OKAZAKI, Atsugi (JP); Shingo EGUCHI, Atsugi (JP); Sachiko KAWAKAMI, Atsugi (JP); Nobuharu OHSAWA, Zama (JP)

(21) Appl. No.: 19/443,291

(22) Filed: Jan. 8, 2026

(30) Foreign Application Priority Data
Jan. 22, 2025 (JP) 2025-009347

(51) Int. Cl. H10K 59/122; H10K 59/38

(52) U.S. Cl. CPC H10K 59/122; H10K 59/38

(57) ABSTRACT

A display apparatus that can easily have a high resolution is provided. A display apparatus having high display quality is provided. A display apparatus includes a pixel electrode, an EL layer, an upper electrode, a first insulating layer, a partition, a color filter, and a transistor. The transistor is positioned below the pixel electrode and is connected to the pixel electrode. The first insulating layer has an end portion over the pixel electrode. The partition is positioned over the first insulating layer. The EL layer contains a light-emitting compound and is in contact with a top surface of the pixel electrode and a top surface of the first insulating layer. The upper electrode covers a top surface and an end portion of the EL layer and is in contact with the top surface of the first insulating layer and a side surface of the partition. The color filter is positioned above the upper electrode and the partition and has an end portion overlapping with the partition. The partition has conductivity and an inverse tapered shape in a cross-sectional view. Furthermore, in a plan view, a gap is between the partition and the end portion of the first insulating layer.

### BACKGROUND OF THE INVENTION

### 1. Field of the Invention

One embodiment of the present invention relates to a display apparatus. One embodiment of the present invention relates to a method for manufacturing a display apparatus.

Note that one embodiment of the present invention is not limited to the above technical field. Examples of the technical field of one embodiment of the present invention disclosed in this specification and the like include a semiconductor apparatus, a display apparatus, a light-emitting apparatus, a power storage device, a memory device, an electronic appliance, a lighting device, an input device, an input/output device, driving methods thereof, and manufacturing methods thereof. The semiconductor apparatus generally means an apparatus that can function by utilizing semiconductor characteristics.

### 2. Description of the Related Art

In recent years, higher-resolution display panels have been required. Examples of appliances that require high-resolution display panels include a smartphone, a tablet terminal, and a laptop computer. Furthermore, a higher resolution has been required for a stationary display apparatus such as a television apparatus or a monitor apparatus along with an increase in definition. An appliance absolutely required to have a high-resolution display panel is an appliance for virtual reality (VR) or augmented reality (AR).

Typical examples of the display apparatus that can be used for a display panel include a liquid crystal display apparatus, a light-emitting apparatus including a light-emitting element such as an organic electroluminescent (EL) element or a light-emitting diode (LED), and electronic paper performing display by an electrophoretic method or the like.

The organic EL element generally has a structure in which a layer containing a light-emitting organic compound is provided between a pair of electrodes. By voltage application to this element, light emission can be obtained from the light-emitting organic compound. A display apparatus using such an organic EL element does not need a backlight that is necessary for a liquid crystal display apparatus or the like; thus, a thin, lightweight, high-contrast, and low-power-consumption display apparatus can be obtained. Patent Document 1, for example, discloses an example of a display apparatus using an organic EL element.

A method using a metal mask is known as a method for separately forming organic EL elements but has issues with an aperture ratio, a resolution, an increase in substrate area, and the like. Patent Document 2 discloses a method for separately forming organic EL elements by a photolithography method without using a metal mask.

### REFERENCES

[Patent Document 1] Japanese Published Patent Application No. 2002-324673

[Patent Document 2] PCT International Publication No. 2023/285907

### SUMMARY OF THE INVENTION

An object of one embodiment of the present invention is to provide a display apparatus that can easily have a high resolution and a method for manufacturing the display apparatus. An object of one embodiment of the present invention is to provide a display apparatus having both high display quality and high resolution. An object of one embodiment of the present invention is to provide a high-contrast display apparatus. An object of one embodiment of the present invention is to provide a highly reliable display apparatus.

An object of one embodiment of the present invention is to provide a display apparatus having a novel structure or a method for manufacturing the display apparatus. An object of one embodiment of the present invention is to provide a method for manufacturing the above display apparatus with high yield. An object of one embodiment of the present invention is to at least alleviate at least one of the issues of the conventional art.

One embodiment of the present invention is a display apparatus including a pixel electrode, an EL layer, an upper electrode, a first insulating layer, a partition, a color filter, and a transistor. The transistor is positioned below the pixel electrode and is connected to the pixel electrode. The first insulating layer has an end portion over the pixel electrode. The partition is positioned over the first insulating layer. The EL layer contains a light-emitting compound and is in contact with a top surface of the pixel electrode and a top surface of the first insulating layer. The upper electrode covers a top surface and an end portion of the EL layer and is in contact with the top surface of the first insulating layer and a side surface of the partition. The color filter is positioned above the upper electrode and the partition and has an end portion overlapping with the partition. The partition has conductivity and an inverse tapered shape in a cross-sectional view. Furthermore, a gap is between the partition and the end portion of the first insulating layer.

Another embodiment of the present invention is a display apparatus including a first pixel electrode, a second pixel electrode, a first EL layer, a second EL layer, a first upper electrode, a second upper electrode, a first insulating layer, a partition, a first color filter, a second color filter, and a transistor. The transistor is positioned below the first pixel electrode and is connected to the first pixel electrode. The first insulating layer has end portions over the first pixel electrode and the second pixel electrode. The partition is positioned over the first insulating layer. The first EL layer contains a first light-emitting compound and is in contact with a top surface of the first pixel electrode and a top surface of the first insulating layer. The second EL layer contains a second light-emitting compound and is in contact with a top surface of the second pixel electrode and the top surface of the first insulating layer. The first upper electrode covers a top surface and an end portion of the first EL layer and is in contact with a part of the top surface of the first insulating layer and a part of a side surface of the partition. The second upper electrode covers a top surface and an end portion of the second EL layer and is in contact with another part of the top surface of the first insulating layer and another part of the side surface of the partition. The first color filter is positioned above the first upper electrode and the partition and has an end portion overlapping with the partition. The second color filter is positioned above the second upper electrode and the partition and has an end portion overlapping with the partition. The partition has conductivity and an inverse tapered shape in a cross-sectional view. Furthermore, a gap is between the partition and the end portion of the first insulating layer over the first pixel electrode.

In the above embodiment, the EL layer is preferably configured to emit white light. In that case, the color filter preferably contains a metal, a pigment, or a dye.

In the above embodiment, the EL layer is preferably configured to emit blue light or light having a shorter wavelength than the blue light. In that case, a wavelength conversion layer is preferably provided instead of the color filter. The wavelength conversion layer contains a quantum dot or a fluorescent material.

In either of the above embodiments, an angle between the side surface of the partition and a contact surface of the partition with the first insulating layer is preferably greater than or equal to 95° and less than or equal to 150°.

In either of the above embodiments, the partition preferably contains indium.

In either of the above embodiments, the transistor preferably contains a metal oxide in a semiconductor layer where a channel is formed.

According to one embodiment of the present invention, a display apparatus that can easily have a high resolution and a method for manufacturing the display apparatus can be provided. A display apparatus having both high display quality and high resolution can be provided. A high-contrast display apparatus can be provided. A highly reliable display apparatus can be provided.

According to one embodiment of the present invention, a display apparatus having a novel structure or a method for manufacturing the display apparatus can be provided. A method for manufacturing the above display apparatus with high yield can be provided. According to one embodiment of the present invention, at least one of the issues of the conventional art can be at least alleviated.

Note that the description of these effects does not preclude the existence of other effects. One embodiment of the present invention does not necessarily need to have all of these effects. Other effects can be derived from the description of the specification, the drawings, the claims, and the like.

### BRIEF DESCRIPTION OF THE DRAWINGS

FIGS. 1A and 1B illustrate structure examples of a display apparatus.

FIGS. 2A and 2B illustrate a structure example of the display apparatus.

FIGS. 3A to 3C illustrate structure examples of the display apparatus.

FIGS. 4A to 4F illustrate an example of a method for manufacturing the display apparatus.

FIGS. 5A to 5C illustrate examples of the method for manufacturing the display apparatus.

FIGS. 6A and 6B illustrate the example of the method for manufacturing the display apparatus.

FIGS. 7A to 7E illustrate examples of the method for manufacturing the display apparatus.

FIGS. 8A and 8B illustrate structure examples of manufacturing apparatuses for display apparatuses.

FIG. 9 illustrates a structure example of a display apparatus.

FIG. 10 illustrates the structure example of the display apparatus.

FIGS. 11A and 11B illustrate a structure example of a display apparatus.

FIGS. 12A and 12B illustrate a structure example of a display apparatus.

FIG. 13 illustrates a structure example of a display apparatus.

FIG. 14 illustrates a structure example of a display apparatus.

FIG. 15 illustrates a structure example of a display apparatus.

FIGS. 16A to 16F illustrate structure examples of light-emitting devices.

FIGS. 17A to 17C illustrate structure examples of light-emitting devices.

FIGS. 18A to 18D illustrate structure examples of electronic appliances.

FIGS. 19A to 19F illustrate structure examples of electronic appliances.

FIGS. 20A to 20G illustrate structure examples of electronic appliances.

FIGS. 21A and 21B illustrate a structure example of an electronic appliance. FIG. 21C illustrates a state where the electronic appliance is in use.

### DETAILED DESCRIPTION OF THE INVENTION

Embodiments will be described below with reference to the drawings. Note that the embodiments can be implemented in many different modes, and it will be readily understood by those skilled in the art that modes and details thereof can be changed in various ways without departing from the spirit and scope thereof. Therefore, the present invention should not be construed as being limited to the description of the embodiments below.

Note that in structures of the invention described below, the same portions or portions having similar functions are denoted by the same reference numeral in different drawings, and the description thereof is not repeated. The same hatching pattern is used for portions having similar functions, and the portions are not denoted by specific reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that ordinal numbers such as “first” and “second” in this specification and the like are used in order to avoid confusion among components and do not limit the number of components.

In this specification and the like, the expression “having substantially the same top surface shape” means that the outlines of stacked layers at least partly overlap with each other. For example, the expression includes the case of processing upper and lower layers with use of the same mask pattern or mask patterns that are partly the same. The expression “having substantially the same top surface shape” also sometimes includes the case where the outlines do not completely overlap with each other; for instance, the outline of the upper layer may be positioned inward or outward from the outline of the lower layer.

Note that in this specification and the like, the top surface shape of a component means the outline shape of the component in a plan view. The plan view means that the component is observed from a direction normal to a surface where the component is formed or from a direction normal to a surface of a support (e.g., a substrate) where the component is formed.

Note that the expressions indicating directions such as “over” and “under” are basically used to correspond to the directions in drawings. However, in some cases, the term “over” or “under” in the specification indicates a direction that does not correspond to the apparent direction in the drawings, for the purpose of easy description or the like. For example, in the description of the stacking order (or formation order) of a stack or the like, the case where a surface on which the stack is provided (e.g., a formation surface, a support surface, a bonding surface, or a planar surface) is positioned above the stack in drawings is sometimes expressed such that the formation surface is on the lower side and the stack is on the upper side.

In this specification and the like, the terms “film” and “layer” can be interchanged with each other. For example, in some cases, the term “insulating layer” can be interchanged with the term “insulating film”.

Note that in this specification, an EL layer means a layer containing at least a light-emitting substance (also referred to as a light-emitting layer) or a stack including the light-emitting layer provided between a pair of electrodes of a light-emitting element.

In this specification and the like, a structure in which a connector such as a flexible printed circuit (FPC) or a tape carrier package (TCP) is attached to a substrate of a display panel, or a structure in which an IC is mounted on the substrate by a chip on glass (COG) method or the like is referred to as a display panel module or a display module, or simply referred to as a display panel or the like in some cases.

### Embodiment 1

In this embodiment, structure examples and manufacturing method examples of a display apparatus according to one embodiment of the present invention will be described.

One embodiment of the present invention is a display apparatus including a light-emitting element (also referred to as a light-emitting device). The display apparatus includes a light-emitting element that emits white light (also referred to as a white-light-emitting element) and a color filter (also referred to as a coloring layer). The light-emitting element includes a pair of electrodes and an EL layer therebetween. The light-emitting element is preferably an organic electroluminescent element (an organic EL element). For example, the display apparatus can perform full-color display when it includes three kinds of pixels each including a color filter that transmits red (R), green (G), or blue (B) light.

Note that the combination of the white-light-emitting element and the color filter may be changed to a combination of a blue-light-emitting element and a wavelength conversion layer. For example, the wavelength conversion layer can be formed using a quantum dot, a fluorescent material, or the like. The wavelength conversion layer can convert blue light into light having a longer wavelength than blue light (e.g., into green or red light), for example. Thus, the display apparatus can perform full-color display when it includes blue-light-emitting elements, a wavelength conversion layer that converts blue light into red light, and a wavelength conversion layer that converts blue light into green light. Specifically, the display apparatus can perform full-color display when a blue-light-emitting element is used to emit blue light, a blue light-emitting element and a wavelength conversion layer that converts blue light into red light are combined to emit red light, and a blue light-emitting element and a wavelength conversion layer that converts blue light into green light are combined to emit green light, for example.

The light-emitting element can include an EL layer between a pair of electrodes. Here, one of the pair of electrodes is a pixel electrode to which a potential can be individually supplied. The other of the pair of electrodes is a common electrode to which a potential common to a plurality of light-emitting elements is supplied. Thus, when the potential of the pixel electrode is controlled by a circuit including a transistor or the like, the emission luminance of the light-emitting element can be individually controlled for image display.

One advantage of a display apparatus including light-emitting elements of one kind and color filters is that the light-emitting elements can be formed using common materials. For example, only the pixel electrodes of the light-emitting elements are formed separately, and all the light-emitting elements can share a continuous EL layer and a continuous common electrode without separate formation processes. Accordingly, the display apparatus can be manufactured at a lower cost than in the case of separately forming EL layers and the like. Furthermore, the display apparatus does not require separate formation of EL layers using a metal mask or the like and can thus have an extremely high resolution.

On the other hand, when a common EL layer is used, a leakage current may flow through a highly conductive film included in the EL layer between adjacent light-emitting elements, causing unintentional light emission in some cases. This may lead to not only a decrease in display quality due to a decrease in contrast but also an increase in power consumption. Therefore, although it is possible to increase the resolution owing to no need for a metal mask, it is necessary to increase the distance between adjacent light-emitting elements in order to reduce the leakage current. For this reason, the structure including the common EL layer has a limitation on increases in resolution and aperture ratio.

In one embodiment of the present invention, fine patterning of an EL layer is performed without a shadow mask such as a metal mask. Accordingly, island-shaped EL layers can be formed separately for the light-emitting elements, so that substantially no leakage current is generated between the light-emitting elements. Thus, it is possible to obtain a display apparatus having a high resolution and a high aperture ratio, which has been difficult to achieve. Moreover, owing to no leakage current, it is possible to obtain a display apparatus with significantly high vividness, high contrast, and high display quality.

In one embodiment of the present invention, a partition for physically dividing an EL layer is provided between two adjacent light-emitting elements (a first light-emitting element and a second light-emitting element). The partition is a conductive component having an inverse tapered shape. In other words, the partition has a shape such that its upper portion overhangs in the lateral direction beyond the lower portion. The partition is formed to be positioned between two adjacent pixel electrodes. The partition is provided to surround one pixel electrode. In forming EL layers of the first and second light-emitting elements, disconnection of an EL layer by the partition occurs.

In this specification and the like, disconnection refers to a phenomenon in which a layer, a film, an electrode, or the like is divided because of the shape of its formation surface (e.g., a step).

Next, an upper electrode is formed to cover the EL layer and the partition. The upper electrode is formed by a film formation method which provides higher step coverage than a film formation method used for the EL layer. This enables part of the upper electrode to cover the end portion of the EL layer and to be in contact with part of the partition. Then, a protective layer is formed to cover the upper electrode and the partition. The protective layer is preferably formed by an atomic layer deposition (ALD) method, which provides extremely high step coverage. Thus, a film which includes few defects such as pinholes and is suitable for the protective film can be obtained.

In the above manner, the EL layer can be processed without using a metal mask; thus, a display apparatus with an extremely high resolution and a high aperture ratio can be manufactured.

It is difficult to set the distance between island-shaped EL layers to be less than 10 μm by a formation method using a metal mask, for example. In contrast, by the above method, the distance can be decreased to be less than or equal to 3 μm, less than or equal to 2 μm, or less than or equal to 1 μm. For example, with the use of a light exposure apparatus for LSI devices, the distance can be decreased to be less than or equal to 500 nm, less than or equal to 200 nm, less than or equal to 100 nm, or even less than or equal to 50 nm. Accordingly, the area of a non-light-emitting region that may exist between two light-emitting elements can be significantly reduced, and the aperture ratio can be close to 100%. For example, the aperture ratio can be higher than or equal to 50%, higher than or equal to 60%, higher than or equal to 70%, higher than or equal to 80%, or higher than or equal to 90% and lower than 100%.

Furthermore, the size of the EL layer itself can be made much smaller than that of the case of using a metal mask. For example, in the case of using a metal mask for forming EL layers

separately, a variation in the thickness occurs between the center and the edge of the island-shaped EL layer. This causes a reduction in an effective area that can be used as a light-emitting region with respect to the area of the entire EL layer. By contrast, in the above manufacturing method, disconnection by a partition is utilized to form island-shaped EL layers with a uniform thickness. Thus, even when the EL layer has a minute size, almost the whole area can be used as a light-emitting region. Therefore, the above manufacturing method achieves both a high resolution and a high aperture ratio.

As described above, by the above manufacturing method, a display apparatus in which minute light-emitting elements are integrated can be obtained. Accordingly, it is not necessary to conduct a pseudo improvement in resolution with a unique pixel arrangement such as a PenTile pattern. Thus, the display apparatus can have a resolution higher than or equal to 500 ppi, higher than or equal to 1000 ppi, higher than or equal to 2000 ppi, higher than or equal to 3000 ppi, higher than or equal to 5000 ppi, or even higher than or equal to 8000 ppi while having a structure where each pixel includes light-emitting elements of three colors.

More specific examples are described below with reference to drawings.

### Structure Example

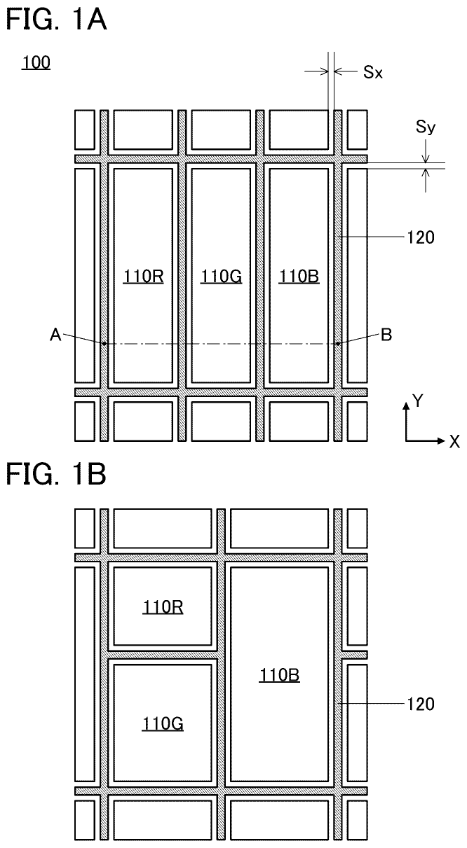

FIG. 1A is a schematic top view of a display apparatus 100. The display apparatus 100 includes a plurality of pixels 110R that exhibit red, a plurality of pixels 110G that exhibit green, and a plurality of pixels 110B that exhibit blue. Each pixel includes a light-emitting element and a color filter. In FIG. 1A, the X direction and the Y direction that are orthogonal to each other are indicated by arrows.

The pixels 110R, 110G, and 110B are arranged in matrices. FIG. 1A illustrates what is called a stripe arrangement, in which light-emitting elements of the same color are arranged in the Y direction. Note that the arrangement of the pixels is not limited thereto; another arrangement such as an S-stripe, delta, zigzag, or PenTile pattern may also be used. FIG. 1B illustrates an example in which the S-stripe pattern is used.

As each of the light-emitting elements in the pixels 110R, 110G, and 110B, an EL element such as an organic light-emitting diode (OLED) or a quantum-dot light-emitting diode (QLED) is preferably used. Examples of a light-emitting substance contained in the EL element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Examples of the light-emitting substance contained in the EL element include not only organic compounds but also inorganic compounds (e.g., quantum dot materials).

In this embodiment, a matter common to components distinguished by alphabet letters or numbers added to a reference numeral (e.g., a pixel electrode 111R and a pixel electrode 111G) is sometimes described using the reference numeral excluding the alphabet letters or numbers (e.g., a pixel electrode 111) without any explanation.

A partition 120 is provided between the pixels. The partition 120 has a lattice-like top surface shape. It can be said that the light-emitting element of the pixel is provided in a region surrounded by the partition 120.

As illustrated in FIG. 1A, a gap is provided between the partition 120 and each pixel in a plan view. FIG. 1A illustrates a gap Sx in the X direction and a gap Sy in the Y direction between the partition 120 and the light-emitting element of the pixel.

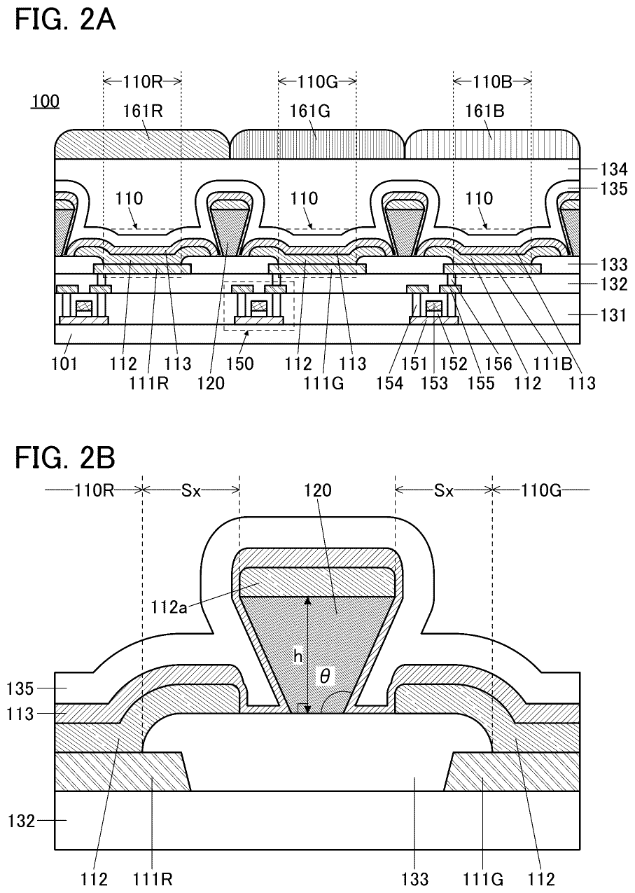

FIG. 2A is a schematic cross-sectional view of the display apparatus 100 along the cutting line A-B in FIG. 1A. The display apparatus 100 includes a plurality of transistors 150, the plurality of pixels 110R, the plurality of pixels 110G, and the plurality of pixels 110B. Each pixel includes a light-emitting element 110 and any one of a color filter 161R, a color filter 161G, and a color filter 161B.

The transistors 150 are provided over a substrate 101. The transistors 150 each include a semiconductor layer 151 in which a channel is formed, an insulating layer 152 functioning as a gate insulating layer, a conductive layer 153 functioning as a gate electrode, and a pair of conductive layers 154 that are in contact with the semiconductor layer 151 and function as a source electrode and a drain electrode. The conductive layers 154 are in contact with the semiconductor layer 151 in opening portions provided in an insulating layer 131 covering the semiconductor layer 151, the insulating layer 152, and the conductive layer 153.

A metal oxide having semiconductor properties (also referred to as an oxide semiconductor) is preferably used for the semiconductor layer 151. As the oxide semiconductor, an oxide semiconductor typified by indium oxide or In—Ga—Zn oxide (IGZO) can be used. Alternatively, the semiconductor layer of the transistor may contain silicon. Examples of silicon include amorphous silicon and crystalline silicon (e.g., low-temperature polysilicon or single crystal silicon).

Other examples of the metal oxide that can be used for the semiconductor layer 151 include tin oxide, zinc oxide, indium tin oxide, indium titanium oxide, indium gallium oxide, indium tungsten oxide, indium zinc oxide, indium gallium aluminum oxide, indium gallium tin oxide, gallium zinc oxide, aluminum zinc oxide, indium aluminum zinc oxide, indium tin zinc oxide, indium titanium zinc oxide, indium gallium zinc oxide, indium gallium tin zinc oxide, and indium gallium aluminum zinc oxide. Other examples include indium tin oxide containing silicon, gallium tin oxide, and aluminum tin oxide.

Although what is called a top-gate transistor, in which a gate electrode is positioned above a semiconductor layer, is given here as an example of the transistor 150, one embodiment of the present invention is not limited thereto. For example, a bottom-gate transistor, in which a gate electrode is positioned below a semiconductor layer, can also be used.

An insulating layer 132 is provided to cover the conductive layers 154 and the insulating layer 131, and the light-emitting elements 110 are provided over the insulating layer 132.

The light-emitting element 110 of the pixel 110R includes an EL layer 112 between a pixel electrode 111R and an upper electrode 113. Similarly, the light-emitting element 110 of the pixel 110G includes an EL layer 112 between a pixel electrode 111G and an upper electrode 113. The light-emitting element 110 of the pixel 110B includes an EL layer 112 between a pixel electrode 111B and an upper electrode 113.

Each of the pixel electrodes 111 is provided over the insulating layer 132. In FIG. 2A, a conductive layer 155 is provided over the insulating layer 131, and a conductive layer 156 is provided in an opening portion in the insulating layer 132 that overlaps with the conductive layer 155. The pixel electrode 111 is connected to the conductive layer 154 through the conductive layers 156 and 155. Thus, each of the pixel electrodes 111 is connected to one of the source electrode and the drain electrode of the transistor 150.

The EL layer 112 of each of the light-emitting elements 110 contains two or more light-emitting organic compounds that emit light of different colors. For example, the EL layer 112 can include a plurality of light-emitting layers each containing a different light-emitting organic compound. For example, a combination of light-emitting layers of the EL layer 112 can be such that white light can be obtained by light emission from the light-emitting layers. Non-limiting examples of such a combination include three kinds of light-emitting layers for red (R), green (G), and blue (B) and two kinds of light-emitting layers for blue and yellow (Y). For example, in the case of two colors, when emission colors of a first light-emitting layer and a second light-emitting layer are complementary colors, the light-emitting element can be configured to emit white light as a whole. To obtain white light emission by using three or more light-emitting layers, the light-emitting element can be configured to emit white light as a whole by combining emission colors of the three or more light-emitting layers.

The EL layer 112 may include one or more of an electron-injection layer, an electron-transport layer, an electron-blocking layer, a hole-injection layer, a hole-transport layer, and a hole-blocking layer in addition to the layer containing a light-emitting organic compound (the light-emitting layer).

A conductive film that transmits visible light is used for one of the pixel electrode 111 and the upper electrode 113, and a reflective conductive film is used for the other. When the pixel electrode 111 is a light-transmitting electrode and the upper electrode 113 is a reflective electrode, a bottom-emission light-emitting element is obtained. When the pixel electrode 111 is a reflective electrode and the upper electrode 113 is a light-transmitting electrode, a top-emission light-emitting element is obtained. Note that when both the pixel electrode 111 and the upper electrode 113 transmit light, a dual-emission display apparatus can be obtained.

A protective layer 135 is provided to cover the upper electrode 113.

The protective layer 135 can have, for example, a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as indium gallium oxide or indium gallium zinc oxide may be used for the protective layer 135. Aluminum oxide and silicon nitride are particularly preferable because of their high barrier property against water.

Note that in this specification and the like, an oxynitride refers to a material in which the oxygen content is higher than the nitrogen content, and a nitride oxide refers to a material in which the nitrogen content is higher than the oxygen content.

As the protective layer 135, a stacked film of an inorganic insulating film and an organic insulating film can be used. For example, a structure in which an organic insulating film is sandwiched between a pair of inorganic insulating films is preferable.

An insulating layer 133 is provided to cover the end portion of the pixel electrode 111. A portion where the insulating layer 133 is not provided over the pixel electrode 111 functions as a light-emitting region of the light-emitting element 110. The end portion of the insulating layer 133 preferably has a tapered shape. Note that the insulating layer 133 is not necessarily provided.

In this specification and the like, the expression “an object has a tapered shape” indicates that the object has a cross-sectional shape in which the angle between a side surface of the object and a contact surface of the object with a formation surface (also referred to as a taper angle) is greater than 0° and less than 90°, and the thickness continuously increases from the end portion. Meanwhile, the expression “an object has an inverse tapered shape” indicates that the angle between a side surface of the object and a contact surface of the object with a formation surface is greater than 90° and less than 180°.

The insulating layer 133 preferably contains an organic resin. Using an organic resin for the insulating layer 133 can increase adhesion between the insulating layer 133 and the EL layer 112, so that the manufacturing yield can be improved. In particular, in the case of processing into EL layers by etching, it is preferable to use the insulating layer 133 having high adhesion with the EL layers, in which case a defect such as separation of the EL layers after etching can be decreased.

When an organic resin is used for the insulating layer 133, the insulating layer 133 can have a flat surface and a gently curved surface. Thus, coverage with a film formed over the insulating layer 133 can be improved.

Examples of materials that can be used for the insulating layer 133 include an acrylic resin, a polyimide resin, an epoxy resin, a polyamide resin, a polyimide-amide resin, a siloxane resin, a benzocyclobutene-based resin, a phenol resin, and precursors of these resins.

The EL layer 112 includes a region in contact with the top surface of the pixel electrode 111 and a region in contact with the surface of the insulating layer 133. The end portion of the EL layer 112 is positioned over the insulating layer 133.

The partition 120 is provided over the insulating layer 133. The partition 120 has conductivity and an inverse tapered shape.

An insulating layer 134 is provided over the protective layer 135, and the color filter 161R, the color filter 161G, and the color filter 161B are provided over the insulating layer 134.

The insulating layer 134 preferably serves as a planarization film. When the insulating layer 134 has a flat top surface, the thicknesses of the color filters 161 are less likely to vary, so that color unevenness can be inhibited. The insulating layer 134 preferably has a light-transmitting property with respect to visible light. The higher the degree of transparency of the insulating layer 134 is, the more efficiently light from the light-emitting element 110 can be delivered to the coloring layer, leading to improved light extraction efficiency. Examples of resin materials that can be used for the insulating layer 134 include an acrylic resin, a polyimide resin, an epoxy resin, a polyamide resin, a polyimide-amide resin, a siloxane resin, a benzocyclobutene-based resin, a phenol resin, and precursors of these resins.

The color filter 161R is provided to overlap with at least the pixel electrode 111R and has a function of transmitting red light and blocking (absorbing or reflecting) light of the other colors. The color filter 161G is provided to overlap with at least the pixel electrode 111G and has a function of transmitting green light and blocking light of the other colors. The color filter 161B is provided to overlap with at least the pixel electrode 111B and has a function of transmitting blue light and blocking light of the other colors. Each of the color filters 161 is preferably provided such that its end portion overlaps with the partition 120. When the two adjacent color filters 161 partly overlap with each other, white light can be prevented from leaking through a gap between the color filters 161, whereby a high-contrast display apparatus can be obtained.

For each of the color filters 161, a resin material in which one or more of a metal, an alloy, a pigment, and a dye are dispersed can be used. The color filters 161 can be formed in desired positions by a photolithography method, an inkjet method, or the like.

Here, a structure can also be employed in which a light-emitting element that emits blue light or light having a shorter wavelength than blue light is used as the light-emitting element 110 and a wavelength conversion layer is provided instead of the color filter 161. In that case, the wavelength conversion layer provided in each of the green pixel 110G, the red pixel 110R, and the blue pixel 110B can be formed using a resin or the like containing a wavelength conversion material to convert light emitted from the light-emitting element 110 into green light, red light, or blue light. In the case where a light-emitting element that emits blue light is used as the light-emitting element 110, a wavelength conversion layer is not necessarily provided in the blue pixel 110B. As the wavelength conversion material, a fluorescent material, a quantum dot, or the like can be used.

FIG. 2B is an enlarged view of the pixel 110R, the pixel 110G, the partition 120 positioned therebetween, and the vicinity thereof.

The end portion of each of the EL layers 112 is positioned over the insulating layer 133. Each of the upper electrodes 113 covers the end portion of the EL layer 112 and is in contact with part of the top surface of the insulating layer 133 and part of the side surface of the partition 120.

In some cases, the upper electrode 113 is divided into a portion that covers the end portion of the EL layer 112 and is in contact with the partition 120 and a portion that is positioned over the partition 120. Over the partition 120, an EL layer 112a is provided between the partition 120 and the upper electrode 113.

Since the upper electrodes 113 of the two pixels provided with the partition 120 therebetween are both in contact with the partition 120 having conductivity, it can be said that the upper electrodes 113 are connected to each other through the partition 120. Thus, even when the upper electrode 113 is divided in the vicinity of the side surfaces of the partition 120, a common potential is supplied to the divided upper electrodes through the partition 120. As illustrated in FIG. 1A and the like, the partition 120 is provided in a lattice-like shape so as to extend among the light-emitting elements 110; thus, the upper electrodes 113 of all the light-emitting elements 110 are connected to each other through the partition 120. The partition 120 also functions as a wiring for supplying potentials to the upper electrodes 113 of the light-emitting elements 110.

As illustrated in FIG. 2B, end portions of the insulating layer 133 are positioned over the pixel electrode 111R and the pixel electrode 111G. A region between the end portion of the insulating layer 133 and the outermost end portion of the partition 120 corresponds to the gap Sx. The gap Sx can also be expressed as a region between the end portion of a light-emitting region of the light-emitting element 110 and the outermost end portion of the partition 120. As illustrated in FIGS. 1A and 2B, the width of the gap Sx in a plan view is, for example, the distance between the end portion of the light-emitting region of the light-emitting element 110 and the end portion of the partition 120. Owing to the gap Sx, the end portion of the EL layer 112 which is disconnected by the partition 120 during the formation of the EL layer 112 can be positioned not over the pixel electrode 111 but over the insulating layer 133. For example, in the case where the end portion of the EL layer 112 is positioned over the pixel electrode 111, the upper electrode 113 covering the EL layer 112 might be in contact with the pixel electrode 111, causing a short circuit between these electrodes. Thus, in order also to form the EL layer 112 such that its end portion is certainly positioned over the insulating layer 133, it is important to provide the gap Sx between the partition 120 and the end portion of the insulating layer 133. Note that the same applies to the gap Sy.

The height h of the partition 120 is preferably larger than the thickness of the EL layer 112. The taper angle θ of the partition 120 can be greater than 90° and less than 180°. As the taper angle θ becomes closer to 90°, the partition 120 and the upper electrode 113 become more likely to be in contact with each other at the time of forming the upper electrode 113, whereas the gap between the partition 120 and the end portion of the EL layer 112 becomes smaller, which might make it impossible to provide a space for the contact between the upper electrode 113 and the partition 120. Specifically, for example, the upper electrode 113 might have difficulty entering a region between the EL layer 112 and the partition 120. As the taper angle θ becomes closer to 180°, the EL layer 112 becomes more likely to be disconnected, whereas it becomes more difficult to make the upper electrode 113 and the partition 120 in contact with each other. Thus, the taper angle θ is preferably greater than or equal to 95° and less than or equal to 150°, further preferably greater than or equal to 100° and less than or equal to 135°, for example.

A variety of conductive materials can be used for the partition 120. For example, a metal, an alloy, an oxide conductive material, a nitride conductive material, or the like can be used. Other examples of conductive materials include metal materials such as gold, silver, platinum, magnesium, nickel, tungsten, chromium, molybdenum, iron, cobalt, copper, palladium, titanium, aluminum, yttrium, zirconium, and tantalum and alloy materials containing the metal materials.

The partition 120 preferably contains an oxide conductive material containing indium because its contact resistance with the upper electrode 113 can be reduced. For example, an oxide conductive material typified by indium tin oxide can be used. Alternatively, indium oxide, indium zinc oxide, indium titanium oxide, indium gallium zinc oxide, indium tin zinc oxide, indium titanium zinc oxide, indium gallium tin zinc oxide, or the like can be used. Alternatively, indium tin oxide containing silicon can be used, for example. Alternatively, an oxide conductive material not containing indium, such as zinc oxide, may be used.

With the above-described structure, the EL layer can be physically divided between the adjacent light-emitting elements. Thus, generation of leakage current through the EL layer can be practically eliminated, unlike in the case where divided EL layers of light-emitting elements are in contact with each other or a common EL layer is used for light-emitting elements. Accordingly, unintended light emission can be prevented, so that a display apparatus with a high contrast and high display quality can be obtained. Furthermore, since the EL layer 112 is covered with the upper electrode 113 and the protective layer 135 in a region surrounded by the partition 120, diffusion of impurities such as moisture into the EL layer 112 can be prevented, so that a highly reliable display apparatus can be obtained. With this structure, the EL layers 112 can be formed without using a metal mask, and layers included in the light-emitting elements and layers in the vicinity thereof can all be processed using a photolithography method. Hence, a higher resolution and a higher aperture ratio can be achieved more easily than in the case of using a metal mask.

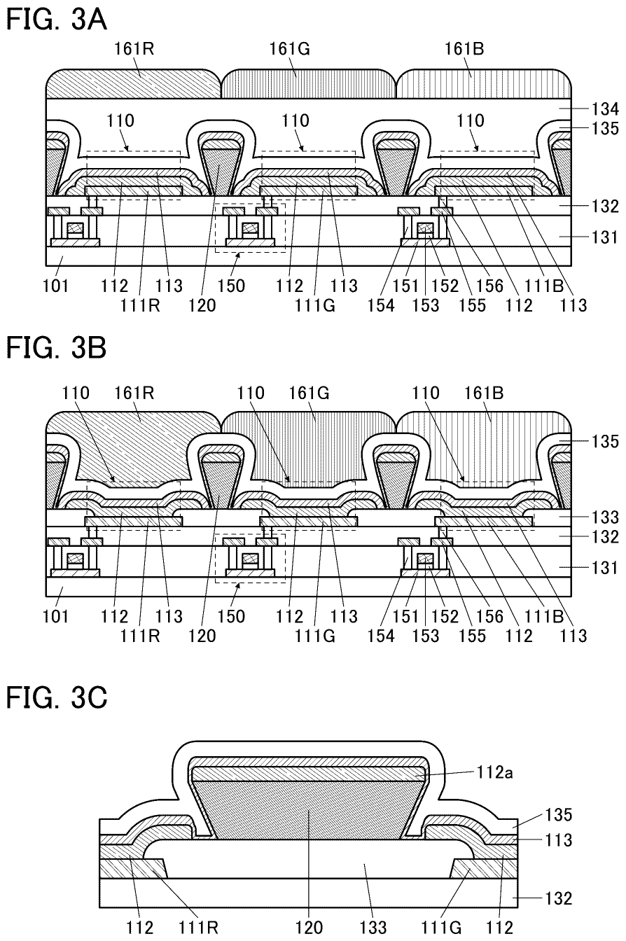

Although FIG. 2A and the like illustrate an example in which the partition 120 is provided over the insulating layer 133, the insulating layer 133 is not necessarily provided. FIG. 3A illustrates an example in which the insulating layer 133 is not provided. In FIG. 3A, like the pixel electrode 111, the partition 120 is provided in contact with the top surface of the insulating layer 132. The end portion of each of the EL layers 112 is positioned over the insulating layer 132, and each of the upper electrodes 113 is in contact with the insulating layer 132 and the partition 120.

Although FIG. 2A illustrates an example in which the color filters 161 are provided over the insulating layer 134, the color filters 161 may be provided directly on the protective layer 135 as illustrated in FIG. 3B. In that case, each of the color filters 161 is preferably provided to fill a depressed portion above the top surface of the protective layer 135 in the region surrounded by the partition 120. Also in that case, processing is preferably performed such that the end portion of the color filter 161 is positioned over the partition 120. Thus, white light emitted from the light-emitting element 110 can be prevented from leaking to the outside.

Although the height of the partition 120 is illustrated as being larger than the width of the partition 120 in FIG. 2A and the like, the actual cross-sectional width of the partition 120 may be larger than its height in some cases. FIG. 3C illustrates an example in which the cross-sectional width of the partition 120 is larger than the height thereof.

The above is the description of the structure examples.

### Example of Manufacturing Method

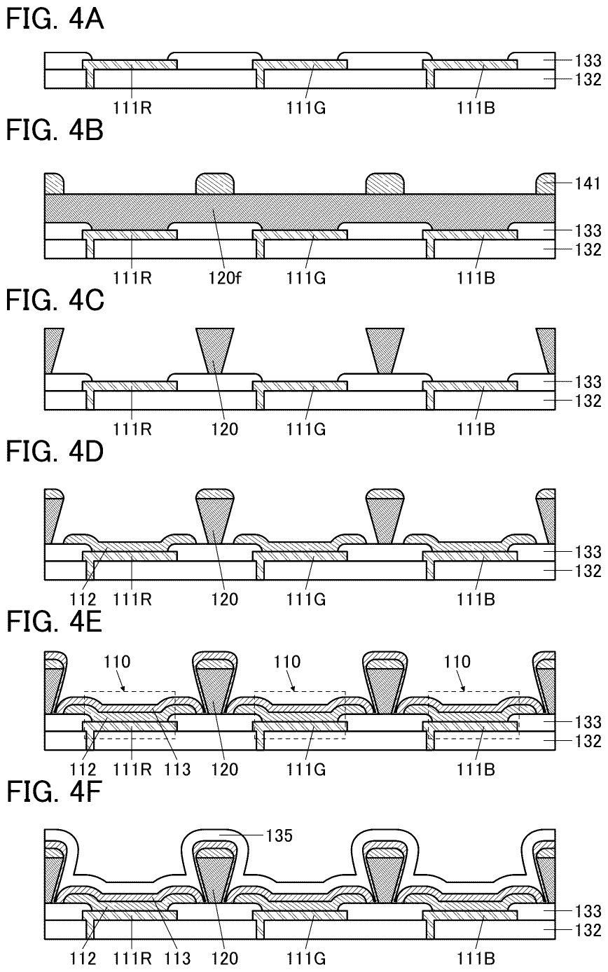

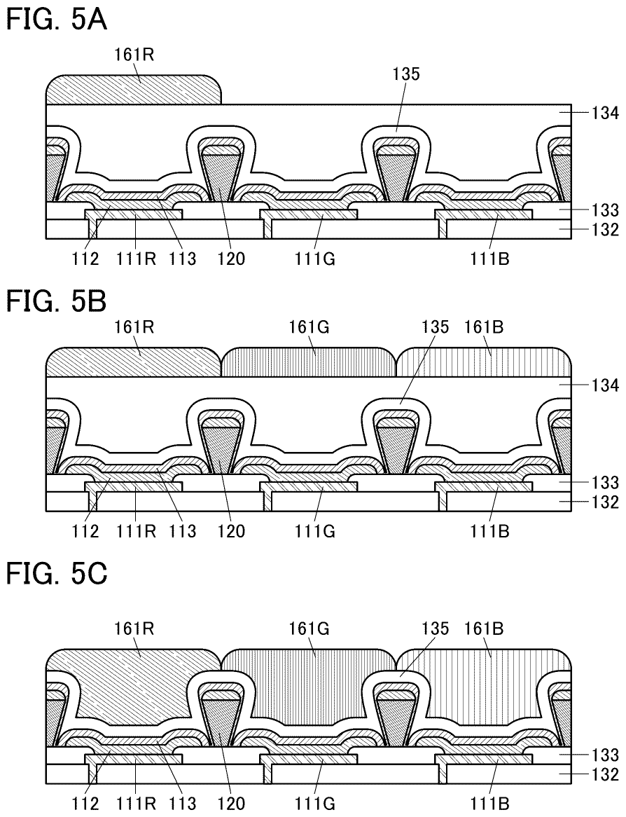

An example of a method for manufacturing the display apparatus of one embodiment of the present invention will be described below with reference to drawings. Here, the description is made with use of the display apparatus 100 shown in the above structure example. FIGS. 4A to 5B are schematic cross-sectional views of steps in the manufacturing method of the display apparatus described as an example below.

Note that thin films included in the display apparatus (e.g., insulating films, semiconductor films, and conductive films) can be formed by a sputtering method, a chemical vapor deposition (CVD) method, a vacuum evaporation method, a pulsed laser deposition (PLD) method, an ALD method, or the like.

Alternatively, thin films included in the display apparatus (e.g., insulating films, semiconductor films, and conductive films) can be formed by a method such as spin coating, dipping, spray coating, ink-jetting, dispensing, screen printing, or offset printing or with a doctor knife, a slit coater, a roll coater, a curtain coater, or a knife coater.

Examples of the sputtering method include an RF sputtering method using a high-frequency power source for a sputtering power source, a DC sputtering method using a DC power source, and a pulsed DC sputtering method in which voltage applied to an electrode is changed in a pulsed manner. For film formation using an insulating target, an RF sputtering method is preferably used. A DC sputtering method is used mainly in the case of film formation using a conductive target. In a DC sputtering method, not only formation of a conductive film but also formation of an insulating film is possible by reactive sputtering using a pulsed DC sputtering method. The pulsed DC sputtering method can be specifically used to form a layer of a compound such as an oxide, a nitride, or a carbide by a reactive sputtering method.

CVD methods can be classified into a plasma enhanced CVD (PECVD) method (also referred to as a plasma CVD method) using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A thermal CVD method yields a film with few defects because of no plasma damage during film formation.

Examples of the ALD method include a thermal ALD method, in which a precursor and a reactant react with each other only by a thermal energy, and a PEALD method, in which a reactant excited by plasma is used.

Unlike a sputtering method, a CVD method and an ALD method are less likely to be influenced by the shape of an object to be processed and thus enable favorable step coverage. In particular, an ALD method allows excellent step coverage and excellent thickness uniformity and can be suitably used to cover a surface of an opening portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the display apparatus can be improved in some cases.

An ALD method in which a plurality of different kinds of precursors are used enables formation of a film with a desired composition. In the case where a plurality of different kinds of precursors are introduced, the number of cycles for each precursor is controlled, whereby a film with a desired composition can be formed. Furthermore, a film whose composition is continuously changed can be formed as in the CVD method.

The thin films included in the display apparatus can be processed by a photolithography method or the like. Besides, a nanoimprinting method, a sandblasting method, a lift-off method, or the like may be employed to process the thin films. Alternatively, island-shaped thin films may be directly formed by a film formation method using a shielding mask such as a metal mask. Alternatively, a directed self-assembly (DSA) method may be used.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure may be performed by a liquid immersion exposure technique. As the light for exposure, extreme ultraviolet (EUV) light or X-rays may also be used. Furthermore, instead of the light used for the exposure, an electron beam can also be used. EUV, X-rays, or an electron beam is preferably used to enable extremely minute processing. When exposure is performed by scanning with the above light or a beam such as an electron beam, a photomask is not needed.

For etching of thin films, a dry etching method, a wet etching method, a sandblasting method, or the like can be used. By a dry etching method, isotropic etching or anisotropic etching can be performed when the conditions of etching are controlled. By a wet etching method, isotropic etching can be performed.

First, the substrate 101 is prepared, and the transistors 150, the insulating layer 131, the insulating layer 132, and the like are formed. Next, a conductive film is formed over the insulating layer 132 and an unnecessary portion of the conductive film is removed by etching, whereby the pixel electrode 111R, the pixel electrode 111G, and the pixel electrode 111B are formed.

In the case where a conductive film that reflects visible light is used for the pixel electrodes 111, it is preferable to use a material (e.g., silver or aluminum) having as high a reflectance as possible in the whole wavelength range of visible light. This can increase both light extraction efficiency and color reproducibility of the light-emitting elements.

Next, the insulating layer 133 is formed to cover the end portions of the pixel electrodes 111 (FIG. 4A). An organic insulating film or an inorganic insulating film can be used as the insulating layer 133. The end portions of the insulating layer 133 preferably have a tapered shape to improve step coverage with an EL film. In particular, when an organic insulating film is used, a photosensitive material is preferably used so that the shape of the end portions can be easily controlled by the conditions of light exposure and development.

Next, a conductive film 120f to be the partition 120 is formed. The conductive film 120f is preferably formed using a material that exhibits high etching rate selectivity with respect to the pixel electrodes 111. The conductive film 120f and the uppermost layer of the pixel electrode 111 are preferably formed using different conductive materials. Alternatively, a film functioning as an etching stopper may be formed before the conductive film 120f is formed, and the film positioned over the pixel electrode 111 may be removed after the etching of the conductive film 120f. In that case, the pixel electrode 111 and the conductive film 120f can be formed using the same conductive material.

Next, a resist mask 141 is formed over the conductive film 120f (FIG. 4B). Then, a portion of the conductive film 120f that is not covered with the resist mask 141 is removed by etching to form the partition 120, and then the resist mask 141 is removed (FIG. 4C).

The conductive film 120f can be etched by an isotropic etching method. For example, the conductive film 120f can be etched by a wet etching method or an isotropic dry etching method. The conductive film 120f is processed such that the lower portion of the conductive film 120f is etched faster than the upper portion thereof, whereby the partition 120 having an inverse tapered shape can be formed.

For example, materials are selected such that the adhesion between the conductive film 120f and the insulating layer 133 is lower than the adhesion between the conductive film 120f and the resist mask 141, whereby the etching rate of the lower portion can be made higher than that of the upper portion and thus the partition 120 having an inverse tapered shape can be formed. For example, when a conductive oxide such as indium tin oxide is used for the conductive film 120f, an organic material with low adhesion to indium tin oxide (e.g., an acrylic resin) can be used for the insulating layer 133.

Next, the EL layer 112 is formed over the pixel electrodes 111 and the partition 120 (FIG. 4D). The EL layer 112 is disconnected by the partition 120 and is thus formed between two regions of the partition 120 and over the partition 120. The EL layer 112 can be formed by either a vacuum evaporation method or a sputtering method or both, for example.

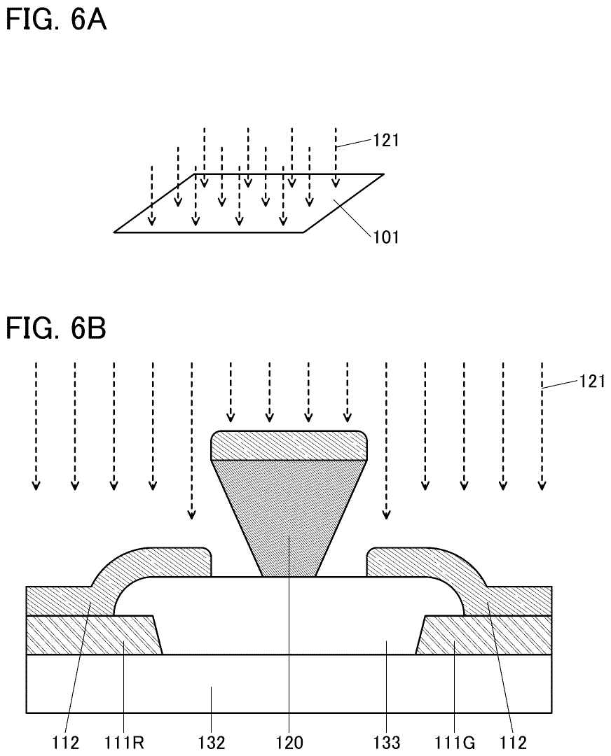

A method for forming the EL layer 112 is described here with reference to FIGS. 6A and 6B. The EL layer 112 is preferably formed by a highly anisotropic film formation method. In other words, as illustrated in FIG. 6A, the EL layer 112 is formed in such a manner that a film material 121 travels in a direction substantially perpendicular to the top surface of the substrate 101. Thus, disconnection can be caused by the partition 120 as illustrated in FIG. 6B. In that case, a sufficient space for entry of the upper electrode 113 is preferably provided between the EL layer 112 and the partition 120.

Next, the upper electrode 113 is formed to cover the EL layer 112 and the like (FIG. 4E). The upper electrode 113 is formed to cover the end portion of the EL layer 112 and to be in contact with at least part of the side surface of the partition 120. The upper electrode 113 can be formed by one or more of a vacuum evaporation method, a sputtering method, and a CVD method.

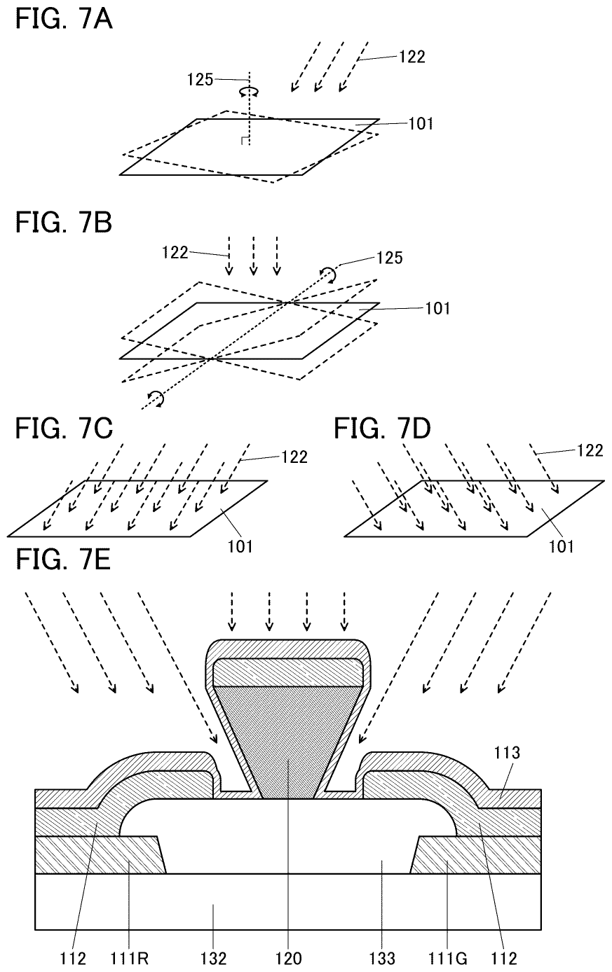

Methods for forming the upper electrode 113 are described with reference to FIGS. 7A to 7E. The upper electrode 113 is preferably formed by a less anisotropic film formation method than that for the EL layer 112. In other words, a film formation method is preferably employed in which the travelling direction of a film material of the upper electrode 113 includes not only a component perpendicular to the top surface of the substrate but also a component oblique thereto. A low-anisotropy film formation method can be obtained by, for example, decreasing the distance between an evaporation source (or a sputtering target) and the substrate, using a plurality of evaporation sources (or sputtering targets), or increasing the area of an evaporation source (or a sputtering target).

Alternatively, it is possible to use a film formation apparatus including a mechanism by which a film material 122 travels in a direction oblique to the top surface of the substrate 101 and the substrate 101 rotates on a rotation axis 125 that is perpendicular to the substrate surface as illustrated in FIG. 7A. Although FIG. 7A illustrates an example in which the rotation axis 125 passes through the center of the substrate 101, the rotation axis 125 may pass through any point on the substrate 101 or may be positioned outside the substrate 101. The rotation axis 125 is not necessarily perpendicular to the surface of the substrate 101.

Alternatively, it is possible to use a film formation apparatus including a mechanism by which the substrate 101 rotates (or swings) on the rotation axis 125 that is parallel to the substrate surface as illustrated in FIG. 7B. In that case, the film material 122 can travel in a direction perpendicular to the rotation axis 125.

With the use of a film formation apparatus including a mechanism like those illustrated in FIGS. 7A and 7B, the film formation process for the upper electrode 113 can include a period in which the film material 122 travels toward the surface of the substrate 101 in an oblique direction as illustrated in FIG. 7C and a period in which the film material 122 travels in the symmetrically opposite oblique direction as illustrated in FIG. 7D. Thus, the upper electrode 113 can also be formed on the side surface of the partition 120 having an inverse tapered shape, as illustrated in FIG. 7E.

Although the cases where the substrate 101 moves are described above as examples, the evaporation source may be moved, or both the substrate 101 and the evaporation source may be moved.

Through the above-described steps, the light-emitting elements 110 can be manufactured as illustrated in FIG. 4E.

Next, the protective layer 135 is formed to cover the upper electrode 113 (FIG. 4F). The protective layer 135 is preferably formed by a film formation method that provides high step coverage, and is preferably formed by a CVD method or an ALD method. In particular, an ALD method is preferable because of less film formation damage to a layer on which a film is formed.

For example, an aluminum oxide film can be formed as the protective layer 135 by an ALD method. In that case, as a precursor containing aluminum, trimethylaluminum, triethylaluminum, triisobutylaluminum, dimethylaluminum hydride, tris(dimethylamino)aluminum, tris(diethylamino)aluminum, aluminum trichloride, or the like is preferably used. As an oxidizer serving as a reactant, for example, ozone (O₃), oxygen (O₂), water (H₂O), nitrogen dioxide (NO₂), dinitrogen monoxide (N₂O), hydrogen peroxide (H₂O₂), or the like can be used, or two or more of these can be used.

The protective layer 135 may have a stacked-layer structure of a film formed by an ALD method and a film formed by a film formation method other than an ALD method (e.g., a CVD method or a sputtering method). An ALD method provides extremely high step coverage but has a lower film formation rate than other film formation methods; the time taken for the film formation step for the protective layer 135 can be shortened by first forming a film with extremely few defects by an ALD method and then forming a thick insulating film by a CVD method or the like.

Next, the insulating layer 134 is formed over the protective layer 135. The insulating layer 134 can be formed in the following manner: a layer containing a material of the insulating layer 134 and a solvent is formed by a coating method or the like, and then the solvent is removed by heat treatment. In addition, the insulating layer 134 can be cured by the heat treatment.

Next, the color filter 161R is formed over the insulating layer 134 (FIG. 5A). The color filter 161R can be formed by a method such as a photolithography method or an inkjet method. After the color filter 161R is formed, heat treatment may be performed to remove a solvent or the like from the color filter.

After that, the color filter 161G and the color filter 161B are formed over the insulating layer 134 by a method similar to that for the color filter 161R (FIG. 5B). Note that there is no limitation on the order of forming the color filters 161.

In the case where the insulating layer 134 is not provided as illustrated in FIG. 3B, the color filters 161 are formed after the protective layer 135 is formed (FIG. 5C).

Through the above-described steps, the display apparatus 100 can be manufactured.

### Example of Film Formation Apparatus

Described below are examples of film formation apparatuses capable of forming an EL layer, an upper electrode, and a protective layer successively without exposure to the air. The film formation apparatuses described below as examples can be used to form the EL layer 112, the upper electrode 113, and the protective layer 135 for each of the light-emitting elements 110.

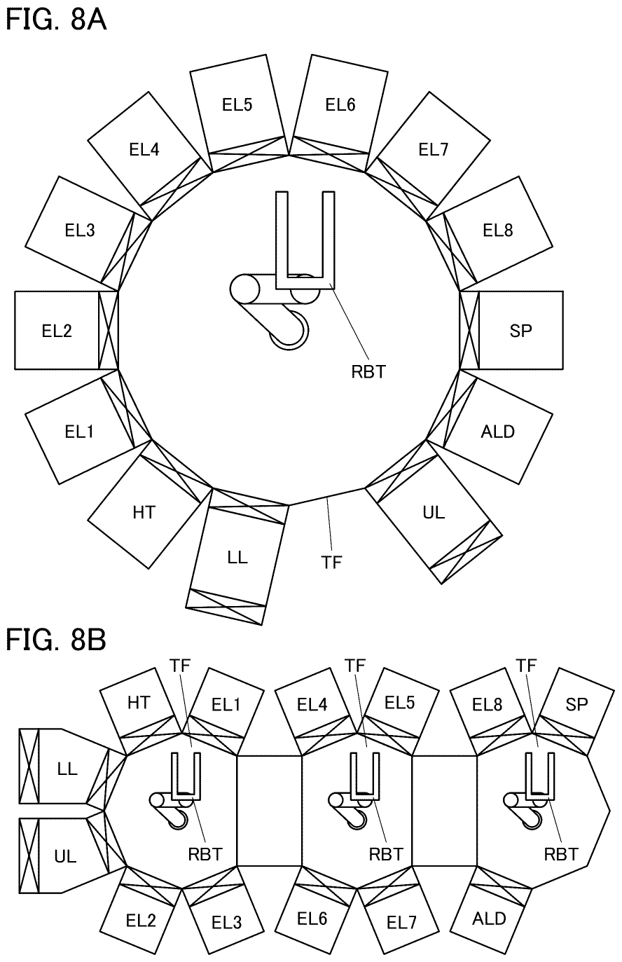

FIG. 8A is a schematic diagram of a film formation apparatus. The film formation apparatus includes a loading chamber LL, an unloading chamber UL, a treatment chamber HT, film formation chambers EL1 to EL8, a film formation chamber ALD, and a film formation chamber SP around a transfer chamber TF. The transfer chamber TF includes a transfer robot RBT, and the transfer robot RBT can load and unload the substrate 101 into and from each chamber. The chambers can also be referred to as rooms.

The transfer chamber TF and each chamber are connected to a vacuum pump and are kept under reduced pressure. A gate valve is provided between the transfer chamber TF and each chamber to separately control the atmosphere, e.g., the pressure or the temperature, of each chamber.

The loading chamber LL is a chamber for loading the substrate 101, and the unloading chamber UL is a chamber for unloading the substrate 101. The loading chamber LL and the unloading chamber UL are each provided with a gate valve that connects to the outside.

In the treatment chamber HT, treatment for heating the substrate 101 can be performed. The treatment chamber HT includes a baking apparatus. For example, a hot-plate baking apparatus or a baking apparatus including a resistive heater or an infrared lamp may be used.

In the film formation chambers EL1 to EL8, films included in the EL layer 112 can be formed. The film formation chambers EL1 to EL8 each include a vacuum evaporation apparatus or a sputtering apparatus, for example.

For example, the film formation chamber EL1 include an apparatus for forming a hole-injection layer; the film formation chamber EL2, a hole-transport layer; the film formation chamber EL3, an electron-blocking layer; the film formation chamber EL4, a light-emitting layer; the film formation chamber EL5, a hole-blocking layer; the film formation chamber EL6, an electron-transport layer; the film formation chamber EL7, an electron-injection layer; and the film formation chamber EL8, a charge-generation layer.

In the film formation chamber SP, the upper electrode 113 can be formed. For example, the film formation chamber SP includes a sputtering apparatus.

In the film formation chamber ALD, the protective layer 135 can be formed. For example, the film formation chamber ALD includes an ALD apparatus.

Although FIG. 8A illustrates an example in which one transfer chamber TF is provided, a plurality of transfer chambers TF may be joined together. FIG. 8B illustrates an example in which three transfer chambers TF are joined. Each of the transfer chambers TF is provided with one transfer robot RBT. In the example illustrated in FIG. 8B, each of the transfer chambers TF can be connected to four to six chambers excluding the loading chamber LL and the unloading chamber UL. In FIG. 8B, up to three more chambers can be provided depending on the application.

Next, an example of a film formation method using either of the film formation apparatuses is described. First, the substrate 101 provided with components up to the partition 120 as illustrated in FIG. 4C is loaded into the film formation apparatus from the loading chamber LL, and heat treatment is performed in the treatment chamber HT. Through this heat treatment, moisture or the like adsorbed on the surface can be removed. Next, the hole-injection layer, the hole-transport layer, the electron-blocking layer, the light-emitting layer, the hole-blocking layer, the electron-transport layer, and the electron-injection layer are sequentially formed in the film formation chambers EL1 to EL7. Next, the upper electrode is formed in the film formation chamber SP. Next, the protective layer 135 is formed in the film formation chamber ALD, and then the substrate 101 is unloaded to the outside from the unloading chamber UL. In the above manner, the EL layer 112, the upper electrode 113, and the protective layer 135 can be formed successively without exposure of the substrate 101 to the air.

The above-described film formation apparatus can also be used to form a light-emitting element having what is called a tandem structure, which includes a plurality of light-emitting layers with a charge-generation layer(s) therebetween.

First, as described above, after heat treatment is performed in the treatment chamber, the substrate 101 is sequentially transferred to the film formation chambers EL1 to EL7, so that hole-injection to electron-injection layers are sequentially formed. Next, a charge-generation layer is formed in the film formation chamber EL8. After that, hole-injection to electron-injection layers are sequentially formed again in the film formation chambers EL1 to EL7. Then, as described above, the upper electrode 113 is formed in the film formation chamber SP, the protective layer 135 is formed in the film formation chamber ALD, and the substrate 101 is unloaded from the unloading chamber UL. This makes it possible to manufacture a light-emitting element having a two-unit tandem structure in which the two light-emitting layers are stacked with the charge-generation layer therebetween.

In the film formation chamber EL8, at least one layer included in the charge-generation layer is formed. At least one of the electron-injection layer and the hole-injection layer formed before and after the film formation step in the film formation chamber EL8 can also serve as a layer included in the charge-generation layer. For example, in the case where the charge-generation layer has a stacked-layer structure of an electron-injection buffer layer, an electron-relay layer, and a p-type layer, the electron-injection layer may have a function of the electron-injection buffer layer, and the hole-injection layer may have a function of the p-type layer. In that case, the electron-relay layer may be formed in the film formation chamber EL8.

In the case of manufacturing a light-emitting element having an N-unit tandem structure (N is a natural number greater than or equal to 2), the film formation in the film formation chambers EL1 to EL8 is repeated N-1 times, the film formation in the film formation chamber EL8 is omitted for the last N-th time, and then the upper electrode 113 and the protective layer 135 are formed.

The above is the description of the film formation apparatuses and the film formation methods using the film formation apparatuses.

### Embodiment 2

In this embodiment, structure examples of the display apparatus of one embodiment of the present invention will be described.

The display apparatus in this embodiment can be a high-resolution display apparatus or a large-sized display apparatus. Accordingly, the display apparatus in this embodiment can be used for display portions of electronic appliances such as a digital camera, a digital video camera, a digital photo frame, a mobile phone, a portable game console, a smart phone, a wristwatch terminal, a tablet terminal, a portable information terminal, and an audio reproducing device, in addition to display portions of electronic appliances with a relatively large screen, such as a television apparatus, a desktop or laptop personal computer, a monitor of a computer or the like, digital signage, and a large game machine like a pachinko machine.

### Display Apparatus 400A

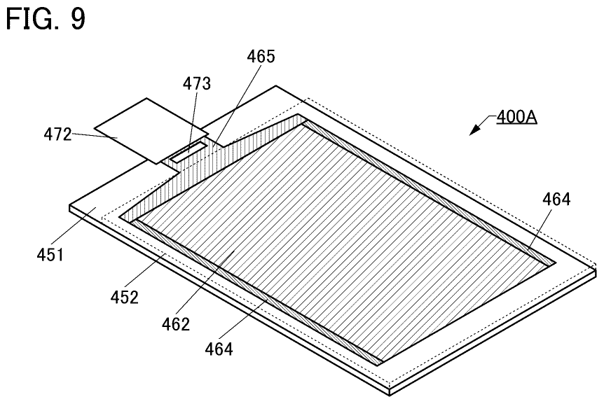

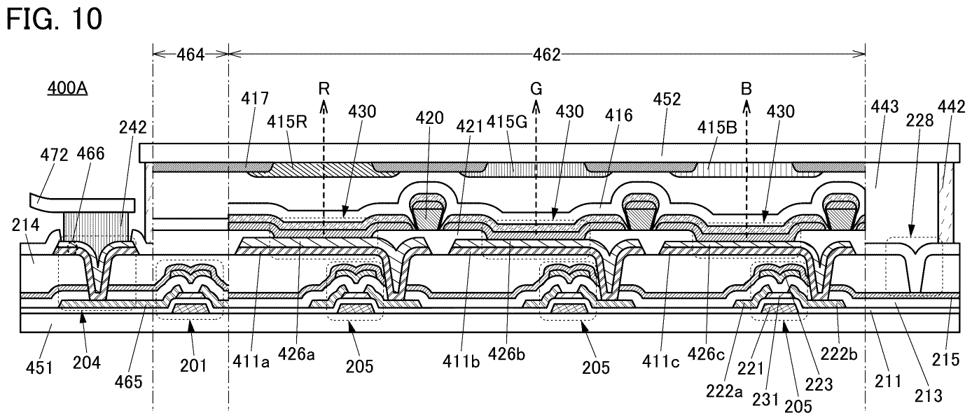

FIG. 9 is a perspective view of a display apparatus 400A, and FIG. 10 is a cross-sectional view of the display apparatus 400A.

In the display apparatus 400A, a substrate 452 and a substrate 451 are bonded to each other. In FIG. 9, the substrate 452 is denoted by a dashed line.

The display apparatus 400A includes a display portion 462, a circuit 464, a wiring 465, and the like. FIG. 9 illustrates an example where an integrated circuit (IC) 473 and an FPC 472 are mounted on the display apparatus 400A. Thus, the structure illustrated in FIG. 9 can be regarded as a display module including the display apparatus 400A, the IC, and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 9 illustrates an example where the IC 473 is provided over the substrate 451 by a chip on glass (COG) method, a chip on film (COF) method, or the like. An IC including a scan line driver circuit, a signal line driver circuit, or the like can be used as the IC 473, for example. Note that the display apparatus 400A and the display module are not necessarily provided with an IC. Alternatively, the IC may be mounted on the FPC by a COF method or the like.

FIG. 10 illustrates an example of cross sections of part of a region including the FPC 472, part of the circuit 464, part of the display portion 462, and part of a region including an end portion in the display apparatus 400A.

The display apparatus 400A illustrated in FIG. 10 includes a transistor 201, a transistor 205, a plurality of light-emitting elements 430 that emit white light, a color filter 415R for red, a color filter 415G for green, a color filter 415B for blue, and the like between the substrate 451 and the substrate 452.

The light-emitting elements described as an example in Embodiment 1 can be used as the light-emitting elements 430. Each of the light-emitting elements 430 includes a pixel electrode 411a, a pixel electrode 411b, or a pixel electrode 411c, an island-shaped EL layer, and an island-shaped upper electrode.

In the case where a pixel of the display apparatus includes three kinds of subpixels that emit light of different colors, the three subpixels can be of three colors of R, G, and B or of three colors of yellow (Y), cyan (C), and magenta (M). In the case where four subpixels are included, the four subpixels can be of four colors of R, G, B, and white (W) or of four colors of R, G, B, and Y.

A protective layer 416 and the substrate 452 are bonded to each other with an adhesive layer 442. A solid sealing structure, a hollow sealing structure, or the like can be employed to seal the light-emitting elements. In FIG. 10, a hollow sealing structure is employed in which a space 443 surrounded by the substrate 452, the adhesive layer 442, and the substrate 451 is filled with an inert gas (e.g., nitrogen or argon). The adhesive layer 442 may overlap with the light-emitting element. The space 443 surrounded by the substrate 452, the adhesive layer 442, and the substrate 451 may be filled with a resin different from that of the adhesive layer 442.

The light-emitting elements 430 each include an optical adjustment layer 426 between the pixel electrode and the EL layer. The light-emitting element 430 in a red pixel includes an optical adjustment layer 426a, the light-emitting element 430 in a green pixel includes an optical adjustment layer 426b, and the light-emitting element 430 in a blue pixel includes an optical adjustment layer 426 c. Embodiment 1 can be referred to for the details of the light-emitting elements. The optical adjustment layers 426 have different thicknesses. The optical adjustment layers 426 preferably contain the same material having a light-transmitting property and conductivity. For the optical adjustment layers 426, a conductive metal oxide film containing indium or zinc is preferably used.

The pixel electrodes 411a, 411b, and 411c are each connected to a conductive layer 222b included in the transistor 205 through an opening portion provided in an insulating layer 213, an insulating layer 214, and an insulating layer 215.

End portions of the pixel electrodes and the optical adjustment layers are covered with an insulating layer 421. The pixel electrodes contain a material that reflects visible light, and the counter electrodes contain a material that transmits visible light.

Light emitted from the light-emitting elements 430 is emitted to the substrate 452 side through the color filters 415. For the substrate 452, a material having a high visible-light-transmitting property is preferably used.

A partition 420 is provided over the insulating layer 421. For the partition 420, the description of the partition 120 in Embodiment 1 can be referred to. The partition 420 is provided in a region overlapping with a light-blocking layer 417. Part of upper electrodes of two light-emitting elements adjacent to each other with the partition 420 therebetween and a layer containing the same material as the EL layers are provided over the partition 420. The protective layer 416 is provided to cover the partition 420.

The transistor 201 and the transistor 205 are formed over the substrate 451. These transistors can be manufactured using the same materials through the same process.

An insulating layer 211, the insulating layer 213, the insulating layer 215, and the insulating layer 214 are provided in this order over the substrate 451. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

A material through which impurities such as water and hydrogen are less likely to diffuse is preferably used for at least one of the insulating layers covering the transistors. This is because such an insulating layer can function as a barrier layer. Such a structure can effectively inhibit diffusion of impurities into the transistors from the outside and improve the reliability of the display apparatus.

An inorganic insulating film is preferably used as each of the insulating layers 211, 213, and 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. Two or more of the above insulating films may also be stacked.

Here, an organic insulating film often has a lower barrier property than an inorganic insulating film. Therefore, the organic insulating film preferably has an opening portion in the vicinity of the end portion of the display apparatus 400A. This can inhibit entry of impurities from the end portion of the display apparatus 400A through the organic insulating film. Alternatively, the organic insulating film may be formed such that its end portion is positioned inward from the end portion of the display apparatus 400A, to prevent the organic insulating film from being exposed at the end portion of the display apparatus 400A.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

In a region 228 illustrated in FIG. 10, an opening portion is formed in the insulating layer 214. This can inhibit entry of impurities into the display portion 462 from the outside through the insulating layer 214 even when an organic insulating film is used as the insulating layer 214. Consequently, the reliability of the display apparatus 400A can be increased.

Each of the transistors 201 and 205 includes a conductive layer 221 functioning as a gate, the insulating layer 211 functioning as the gate insulating layer, a conductive layer 222a and the conductive layer 222b functioning as a source and a drain, a semiconductor layer 231, the insulating layer 213 functioning as the gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. A top-gate transistor or a bottom-gate transistor can be used. Alternatively, gates may be provided above and below a semiconductor layer where a channel is formed.

The structure in which the semiconductor layer where a channel is formed is provided between two gates is employed for each of the transistors 201 and 205. The two gates may be connected to each other and supplied with the same signal to drive the transistor. Alternatively, the threshold voltage of the transistor may be controlled by supplying a potential for controlling the threshold voltage to one of the two gates and supplying a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

It is preferable that a semiconductor layer of a transistor contain a metal oxide (also referred to as an oxide semiconductor). That is, a transistor containing a metal oxide in its channel formation region (hereinafter referred to as an OS transistor) is preferably used in the display apparatus of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains a metal oxide containing indium. In particular, the semiconductor layer preferably contains indium oxide.

The semiconductor layer preferably contains indium, M (M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

It is particularly preferable that an oxide containing indium (In), gallium (Ga), and zinc (Zn) (also referred to as IGZO) be used for the semiconductor layer.

When the semiconductor layer is an In—M—Zn oxide, the atomic proportion of In is preferably higher than or equal to the atomic proportion of M in the In—M—Zn oxide. Examples of the atomic ratio of the metal elements in such an In—M—Zn oxide include In:M:Zn−1:1:1, 1:1:1.2, 2:1:3, 3:1:2, 4:2:3, 4:2:4.1, 5:1:3, 5:1:6, 5:1:7, 5:1:8, 6:1:6, and 5:2:5 and an atomic ratio in the neighborhood thereof. Note that the neighborhood of the atomic ratio includes ±30% of an intended atomic ratio.

For example, when the atomic ratio is described as In:Ga:Zn=4:2:3 or being in the neighborhood thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or being in the neighborhood thereof, the case is included where the atomic proportion of Ga is greater than 0.5 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or being in the neighborhood thereof, the case is included where the atomic proportion of Ga is greater than 0.5 and less than or equal to 2 and the atomic proportion of Zn is greater than 0.5 and less than or equal to 2 with the atomic proportion of In being 1.

The transistor included in the circuit 464 and the transistor included in the display portion 462 may have the same structure or different structures. One structure or two or more kinds of structures may be employed for a plurality of transistors included in the circuit 464. Similarly, one structure or two or more kinds of structures may be employed for a plurality of transistors included in the display portion 462.

A connection portion 204 is provided in a region of the substrate 451 where the substrate 452 does not overlap. In the connection portion 204, the wiring 465 is electrically connected to the FPC 472 through a conductive layer 466 and a connection layer 242. An example is illustrated in which the conductive layer 466 has a stacked-layer structure of a conductive film obtained by processing the same conductive film as the pixel electrode and a conductive film obtained by processing the same conductive film as the optical adjustment layer. On the top surface of the connection portion 204, the conductive layer 466 is exposed. Thus, the connection portion 204 and the FPC 472 can be electrically connected to each other through the connection layer 242.

The light-blocking layer 417 is preferably provided on the surface of the substrate 452 on the substrate 451 side. A variety of optical members can be arranged on the outer surface of the substrate 452. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film inhibiting the attachment of stain, a hard coat film inhibiting generation of a scratch caused by the use, an impact-absorbing layer, or the like may be arranged on the outer surface of the substrate 452.

Providing the protective layer 416 that covers the light-emitting element can inhibit impurities such as water from entering the light-emitting element and increase the reliability of the light-emitting element.

In the region 228 in the vicinity of the end portion of the display apparatus 400A, the insulating layer 215 and the protective layer 416 are preferably in contact with each other through the opening portion in the insulating layer 214. In particular, the inorganic insulating film included in the insulating layer 215 and an inorganic insulating film included in the protective layer 416 are preferably in contact with each other. This can inhibit entry of impurities into the display portion 462 from the outside through the organic insulating film. Consequently, the reliability of the display apparatus 400A can be increased.

The protective layer 416 may have a stacked-layer structure of an organic insulating film and an inorganic insulating film. In that case, an end portion of the inorganic insulating film preferably extends beyond an end portion of the organic insulating film.

For each of the substrates 451 and 452, glass, quartz, ceramics, sapphire, a resin, a metal, an alloy, a semiconductor, or the like can be used. The substrate on the side from which light from the light-emitting element is extracted is formed using a material that transmits the light. When the substrates 451 and 452 are formed using a flexible material, the flexibility of the display apparatus can be increased. Furthermore, a polarizing plate may be used as the substrate 451 or the substrate 452.

For each of the substrates 451 and 452, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for one or both of the substrates 451 and 452.

In the case where a circularly polarizing plate overlaps with the display apparatus, a highly optically isotropic substrate is preferably used as the substrate included in the display apparatus. A highly optically isotropic substrate has a low birefringence (in other words, a small amount of birefringence).

The absolute value of a retardation (phase difference) of a highly optically isotropic substrate is preferably less than or equal to 30 nm, further preferably less than or equal to 20 nm, still further preferably less than or equal to 10 nm.

Examples of a highly optically isotropic film include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of the display panel might be changed, e.g., creases are generated. Thus, as the substrate, a film with a low water absorption rate is preferably used. For example, the water absorption rate of the film is preferably 1% or lower, further preferably 0.1% or lower, still further preferably 0.01% or lower.

The adhesive layer 442 can be formed using any of a variety of curable adhesives, e.g., a reactive curable adhesive, a thermosetting adhesive, an anaerobic adhesive, or a photocurable adhesive such as an ultraviolet curable adhesive. Examples of these adhesives include an epoxy resin, an acrylic resin, a silicone resin, a phenol resin, a polyimide resin, an imide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component resin may be used. An adhesive sheet or the like may be used.

For the connection layer 242, an anisotropic conductive film (ACF), an anisotropic conductive paste (ACP), or the like can be used.

As materials for the gates, the source, and the drain of each transistor and conductive layers functioning as wirings and electrodes included in the display apparatus, any of metals such as aluminum, titanium, chromium, nickel, copper, yttrium, zirconium, molybdenum, silver, tantalum, and tungsten, or an alloy containing any of these metals as its main component can be used, for example. A single-layer structure or a stacked-layer structure including a film containing any of these materials can be used.

Examples of light-transmitting conductive materials include graphene and a conductive oxide such as indium oxide, indium tin oxide, indium zinc oxide, zinc oxide, or zinc oxide containing gallium. Other examples include a metal material such as gold, silver, platinum, magnesium, nickel, tungsten, chromium, molybdenum, iron, cobalt, copper, palladium, or titanium, and an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to transmit light. Alternatively, a stacked film of any of the above materials can be used for the conductive layers. For example, a stacked film of indium tin oxide and an alloy of silver and magnesium is preferably used because conductivity can be increased. These can also be used for conductive layers such as wirings and electrodes included in the display apparatus, and conductive layers (e.g., a conductive layer functioning as a pixel electrode or a common electrode) included in a light-emitting element.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

### Display Apparatus 400B

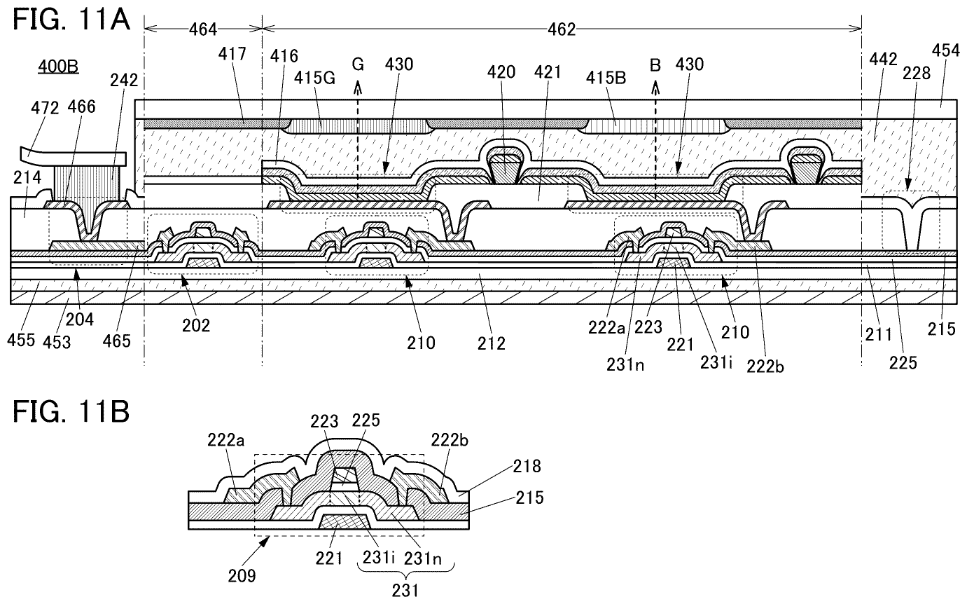

FIG. 11A is a cross-sectional view of a display apparatus 400B. A perspective view of the display apparatus 400B is similar to that of the display apparatus 400A (FIG. 9). FIG. 11A illustrates an example of cross sections of part of a region including the FPC 472, part of the circuit 464, and part of the display portion 462 in the display apparatus 400B. As for the display portion 462, FIG. 11A specifically illustrates an example of a cross section of a region including the light-emitting element 430 provided in a green pixel and the light-emitting element 430 provided in a blue pixel. Note that portions similar to those in the display apparatus 400A are not described in some cases.

The display apparatus 400B illustrated in FIG. 11A includes a transistor 202, a transistor 210, the light-emitting elements 430, the color filter 415G, the color filter 415B, and the like between a substrate 453 and a substrate 454.

The substrate 454 and the protective layer 416 are bonded to each other with the adhesive layer 442. The adhesive layer 442 is provided so as to overlap with the light-emitting elements 430; that is, the display apparatus 400B employs a solid sealing structure.

The substrate 453 and an insulating layer 212 are bonded to each other with an adhesive layer 455.

As a method for manufacturing the display apparatus 400B, first, a formation substrate provided with the insulating layer 212, the transistors, the light-emitting elements, and the like and the substrate 454 provided with the light-blocking layer 417 are bonded to each other with the adhesive layer 442. Then, the substrate 453 is attached to a surface exposed by separation of the formation substrate, whereby the components formed over the formation substrate are transferred to the substrate 453. The substrates 453 and 454 are preferably flexible. Accordingly, the display apparatus 400B can be highly flexible.

The inorganic insulating film that can be used as each of the insulating layers 211, 213, and 215 can be used as the insulating layer 212.

The pixel electrode is connected to the conductive layer 222b included in the transistor 210 through the opening portion provided in the insulating layer 214. The conductive layer 222b is connected to a low-resistance region 231n through an opening portion provided in the insulating layer 215 and an insulating layer 225. The transistor 210 has a function of controlling the driving of the light-emitting element.

An end portion of the pixel electrode is covered with the insulating layer 421.

Light emitted from the light-emitting elements 430 is emitted to the substrate 454 side through the color filters 415. For the substrate 454, a material having a high visible-light-transmitting property is preferably used.

The connection portion 204 is provided in a region of the substrate 453 where the substrate 454 does not overlap. In the connection portion 204, the wiring 465 is electrically connected to the FPC 472 through the conductive layer 466 and the connection layer 242. The conductive layer 466 can be obtained by processing the same conductive film as the pixel electrode. Thus, the connection portion 204 and the FPC 472 can be electrically connected to each other through the connection layer 242.

Each of the transistors 202 and 210 includes the conductive layer 221 functioning as a gate, the insulating layer 211 functioning as a gate insulating layer, a semiconductor layer including a channel formation region 231i and a pair of low-resistance regions 231n, the conductive layer 222a connected to one of the low-resistance regions 231n, the conductive layer 222b connected to the other low-resistance region 231n, the insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned between the conductive layer 223 and the channel formation region 231i.

The conductive layer 222a and the conductive layer 222b are connected to the corresponding low-resistance regions 231n through opening portions provided in the insulating layer 215. One of the conductive layers 222a and 222b functions as a source, and the other functions as a drain.

FIG. 11A illustrates an example where the insulating layer 225 covers the top and side surfaces of the semiconductor layer. The conductive layer 222a and the conductive layer 222b are connected to the corresponding low-resistance regions 231n through the opening portions provided in the insulating layer 225 and the insulating layer 215.

In a transistor 209 illustrated in FIG. 11B, the insulating layer 225 overlaps with the channel formation region 231i of the semiconductor layer 231 and does not overlap with the low-resistance regions 231n. The structure illustrated in FIG. 11B is obtained by processing the insulating layer 225 with the conductive layer 223 as a mask, for example. In FIG. 11B, the insulating layer 215 is provided to cover the insulating layer 225 and the conductive layer 223, and the conductive layer 222a and the conductive layer 222b are connected to the low-resistance regions 231n through the opening portions in the insulating layer 215. Furthermore, an insulating layer 218 covering the transistor may be provided.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 3

In this embodiment, a structure example of a display apparatus different from the above will be described.

The display apparatus in this embodiment can be a high-resolution display apparatus. Thus, the display apparatus in this embodiment can be used for display portions of information terminals (wearable devices) such as watch-type or bracelet-type information terminals and display portions of wearable devices capable of being worn on a head, such as a VR device like a head-mounted display and a glasses-type AR device.

### Display Module

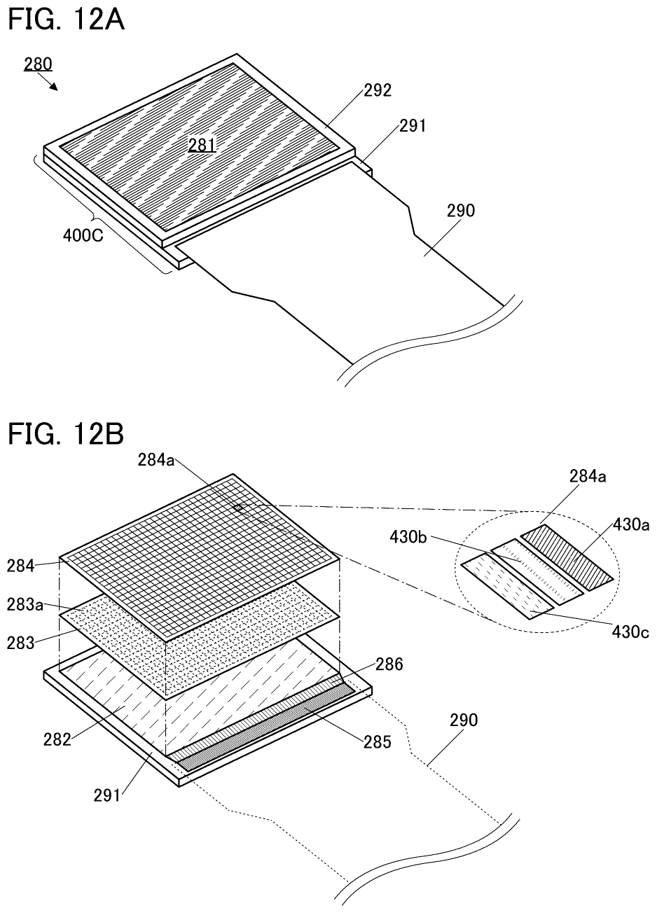

FIG. 12A is a perspective view of a display module 280. The display module 280 includes a display apparatus 400C and an FPC 290. Note that the display apparatus included in the display module 280 is not limited to the display apparatus 400C and may be a display apparatus 400D or a display apparatus 400E described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 12B is a perspective view schematically illustrating the structure on the substrate 291 side. Over the substrate 291, a circuit portion 282, a pixel circuit portion 283 over the circuit portion 282, and the pixel portion 284 over the pixel circuit portion 283 are stacked. In addition, a terminal portion 285 for connection to the FPC 290 is included in a portion over the substrate 291 that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 12B. The pixel 284a includes a pixel 430a, a pixel 430b, and a pixel 430c of different colors. Each of the pixels 430a, 430b, and 430c includes the light-emitting element 430. The plurality of pixels included in the pixel 284a may be arranged in a stripe pattern as illustrated in FIG. 12B. With the stripe pattern that enables high-density arrangement of pixel circuits, a high-resolution display apparatus can be provided. Alternatively, a variety of kinds of patterns such as a delta pattern or a pentile pattern can be employed.

The pixel circuit portion 283 includes a plurality of pixel circuits 283a arranged periodically.

One pixel circuit 283a is a circuit that controls light emission of three light-emitting elements included in one pixel 284a. One pixel circuit 283a may be provided with three circuits each of which controls light emission of one light-emitting element. For example, the pixel circuit 283a can include at least one selection transistor, one current control transistor (driving transistor), and a capacitor for one light-emitting element. A gate signal is input to a gate of the selection transistor, and a source signal is input to one of a source and a drain of the selection transistor. Thus, an active-matrix display apparatus is obtained.

The circuit portion 282 includes a circuit for driving the pixel circuits 283a in the pixel circuit portion 283. For example, the circuit portion 282 preferably includes one or both of a gate line driver circuit and a source line driver circuit. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure where one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be higher than or equal to 40% and lower than 100%, preferably higher than or equal to 50% and lower than or equal to 95%, further preferably higher than or equal to 60% and lower than or equal to 95%. Furthermore, the pixels 284a can be arranged extremely densely and thus the display portion 281 can have significantly high resolution. For example, the pixels 284a are preferably arranged in the display portion 281 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 280 has extremely high resolution, and thus can be suitably used for a device for VR such as a head-mounted display or a glasses-type device for AR. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic appliances including a relatively small display portion. For example, the display module 280 can be suitably used in a display portion of a wearable electronic appliance, such as a wrist watch.

### Display Apparatus 400C

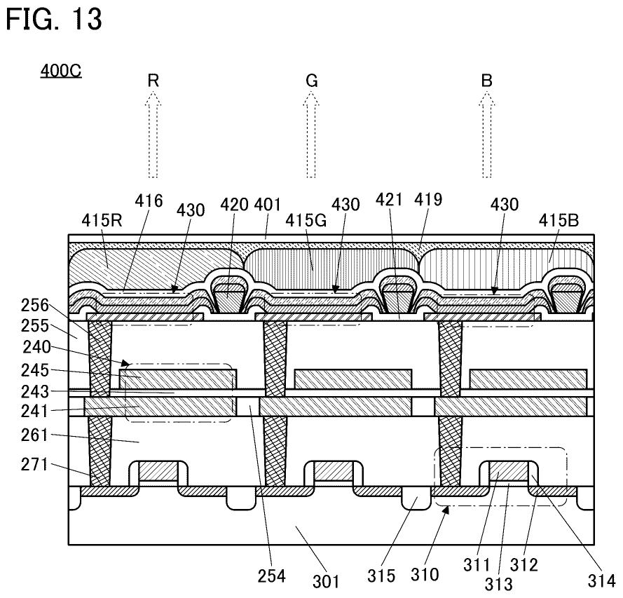

The display apparatus 400C illustrated in FIG. 13 includes a substrate 301, the plurality of light-emitting elements 430, a capacitor 240, the color filter 415R, the color filter 415G, the color filter 415B, a transistor 310, and the like.

The Substrate 301 Corresponds to the Substrate 291 in FIGS. 12a and 12b.

The transistor 310 includes a channel formation region in the substrate 301. As the substrate 301, a semiconductor substrate such as a single crystal silicon substrate can be used, for example. The transistor 310 includes part of the substrate 301, a conductive layer 311, a low-resistance region 312, an insulating layer 313, and an insulating layer 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as one of a source and a drain. The insulating layer 314 is provided to cover the side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 between the conductive layers 241 and 245. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping with the conductive layer 241 with the insulating layer 243 therebetween.

An insulating layer 255 is provided to cover the capacitor 240, and the light-emitting elements 430 and the like are provided over the insulating layer 255. The protective layer 416 is provided over the light-emitting elements 430, and a substrate 401 is bonded to a top surface of the protective layer 416 with a resin layer 419. The substrate 401 corresponds to the substrate 292 in FIG. 12A.

The pixel electrode of the light-emitting element is electrically connected to the one of the source and the drain of the transistor 310 through a plug 256 embedded in the insulating layer 255, the conductive layer 241 embedded in the insulating layer 254, and the plug 271 embedded in the insulating layer 261.

The insulating layer 421 is provided to cover the end portions of the pixel electrodes. An inorganic insulating material is preferably used for the insulating layer 421. For example, an inorganic insulating material such as silicon oxide, silicon nitride, or aluminum oxide can be used.

The partition 420 is provided over the insulating layer 421. For the partition 420, the description of the partition 120 in Embodiment 1 can be referred to. Part of the upper electrodes of the light-emitting elements and a layer containing the same material as the EL layers are provided over the partition 420.

### Display Apparatus 400D

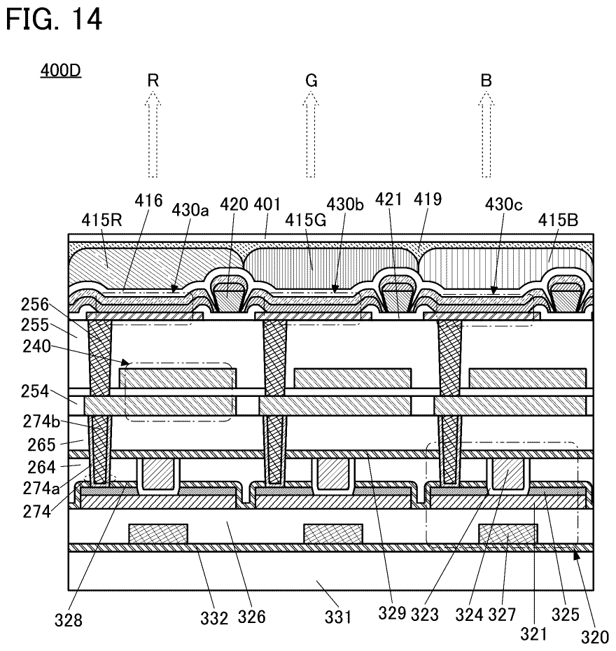

The display apparatus 400D illustrated in FIG. 14 differs from the display apparatus 400C mainly in transistor structure. Note that portions similar to those in the display apparatus 400C are not described in some cases.

A transistor 320 contains a metal oxide (also referred to as an oxide semiconductor) in a semiconductor layer where a channel is formed.

The transistor 320 includes a semiconductor layer 321, an insulating layer 323, a conductive layer 324, a pair of conductive layers 325, an insulating layer 326, and a conductive layer 327.

A substrate 331 corresponds to the substrate 291 illustrated in FIGS. 12A and 12B. As the substrate 331, an insulating substrate or a semiconductor substrate can be used.

An insulating layer 332 is provided over the substrate 331. The insulating layer 332 functions as a barrier layer that prevents diffusion of impurities such as water or hydrogen from the substrate 331 into the transistor 320 and release of oxygen from the semiconductor layer 321 to the insulating layer 332 side. As the insulating layer 332, for example, a film in which hydrogen or oxygen is less likely to diffuse than in a silicon oxide film, such as an aluminum oxide film, a hafnium oxide film, or a silicon nitride film, can be used.

The conductive layer 327 is provided over the insulating layer 332, and the insulating layer 326 is provided to cover the conductive layer 327. The conductive layer 327 functions as a first gate electrode of the transistor 320, and part of the insulating layer 326 functions as a first gate insulating layer. An oxide insulating film such as a silicon oxide film is preferably used as at least part of the insulating layer 326 which is in contact with the semiconductor layer 321. The top surface of the insulating layer 326 is preferably planarized.

The semiconductor layer 321 is provided over the insulating layer 326. A metal oxide film having semiconductor characteristics (also referred to as an oxide semiconductor film) is preferably used for the semiconductor layer 321. A material that can be used for the semiconductor layer 321 is described in detail later.

The pair of conductive layers 325 is provided over and in contact with the semiconductor layer 321, and functions as a source electrode and a drain electrode.

An insulating layer 328 is provided to cover the top and side surfaces of the pair of conductive layers 325, the side surface of the semiconductor layer 321, and the like, and an insulating layer 264 is provided over the insulating layer 328. The insulating layer 328 functions as a barrier layer that prevents diffusion of impurities such as water or hydrogen from the insulating layer 264 and the like into the semiconductor layer 321 and release of oxygen from the semiconductor layer 321. As the insulating layer 328, an insulating film similar to the insulating layer 332 can be used.

An opening portion reaching the semiconductor layer 321 is provided in the insulating layers 328 and 264. The insulating layer 323 that is in contact with the side surfaces of the insulating layers 264 and 328 and the conductive layer 325 and the top surface of the semiconductor layer 321, and the conductive layer 324 fill the inside of the opening portion. The conductive layer 324 functions as a second gate electrode, and the insulating layer 323 functions as a second gate insulating layer.

The top surface of the conductive layer 324, the top surface of the insulating layer 323, and the top surface of the insulating layer 264 are planarized so that they are substantially level with each other, and an insulating layer 329 and an insulating layer 265 are provided to cover these layers.

The insulating layers 264 and 265 each function as an interlayer insulating layer. The insulating layer 329 functions as a barrier layer that prevents diffusion of impurities such as water or hydrogen from the insulating layer 265 or the like into the transistor 320. As the insulating layer 329, an insulating film similar to the insulating layers 328 and 332 can be used.

A plug 274 electrically connected to one of the pair of conductive layers 325 is provided to be embedded in the insulating layers 265, 329, and 264. Here, the plug 274 preferably includes a conductive layer 274a that covers the side surface of an opening portion formed in the insulating layers 265, 329, 264, and 328 and part of the top surface of the conductive layer 325, and a conductive layer 274b in contact with the top surface of the conductive layer 274a. For the conductive layer 274a, a conductive material in which hydrogen and oxygen are less likely to diffuse is preferably used.

Components from the insulating layer 254 to the substrate 401 in the display apparatus 400D are similar to those in the display apparatus 400C.

### Display Apparatus 400E

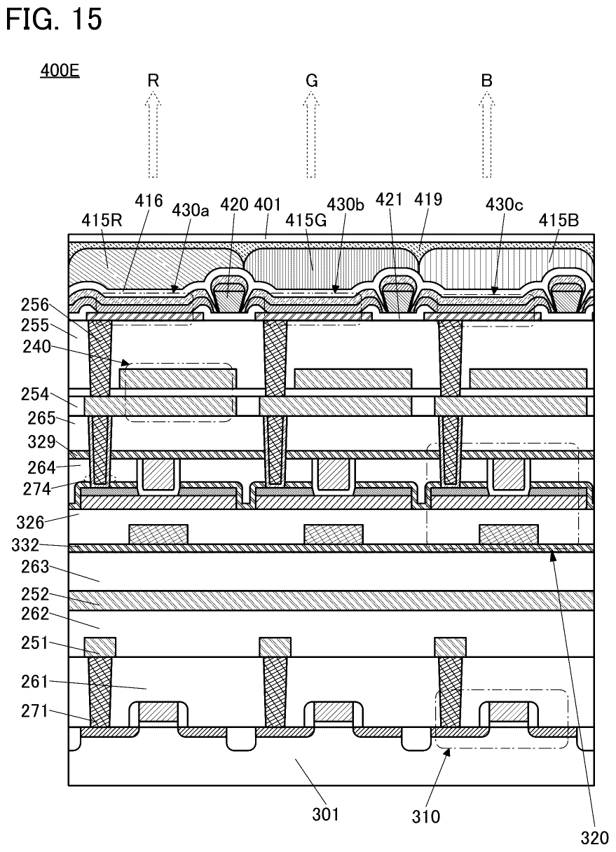

The display apparatus 400E illustrated in FIG. 15 has a structure in which the transistor 310 whose channel is formed in the substrate 301 and the transistor 320 containing a metal oxide in the semiconductor layer where the channel is formed are stacked. Note that portions similar to those in the display apparatuses 400C and 400D are not described in some cases.

The insulating layer 261 is provided to cover the transistor 310, and a conductive layer 251 is provided over the insulating layer 261. An insulating layer 262 is provided to cover the conductive layer 251, and a conductive layer 252 is provided over the insulating layer 262. The conductive layers 251 and 252 each function as a wiring. An insulating layer 263 and the insulating layer 332 are provided to cover the conductive layer 252, and the transistor 320 is provided over the insulating layer 332. The insulating layer 265 is provided to cover the transistor 320, and the capacitor 240 is provided over the insulating layer 265. The capacitor 240 and the transistor 320 are electrically connected to each other through the plug 274.

The transistor 320 can be used as a transistor included in the pixel circuit. The transistor 310 can be used as a transistor included in the pixel circuit or a transistor included in a driver circuit for driving the pixel circuit (a gate line driver circuit or a source line driver circuit). The transistors 310 and 320 can also be used as transistors included in a variety of circuits such as an arithmetic circuit and a memory circuit.

With such a structure, not only the pixel circuit but also the driver circuit or the like can be formed directly under the light-emitting element; thus, the display apparatus can be downsized as compared with the case where the driver circuit is provided around a display region.

At least part of any of the structure examples, the drawings corresponding thereto, and the like described in this embodiment can be combined with any of the other structure examples, the other drawings corresponding thereto, and the like as appropriate.

At least part of this embodiment can be implemented as appropriate in combination with any of the other embodiments described in this specification.

### Embodiment 4

In this embodiment, a light-emitting element (also referred to as a light-emitting device) that can be used in the display apparatus of one embodiment of the present invention will be described.

In this specification and the like, a light-emitting device (also referred to as a light-emitting element) includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer).

In this specification and the like, a device formed using a metal mask or a fine metal mask (FMM, a high-resolution metal mask) is sometimes referred to as a device having a metal mask (MM) structure. In this specification and the like, a device formed without using a metal mask or an FMM is sometimes referred to as a device having a metal maskless (MML) structure.

In this specification and the like, a structure in which light-emitting layers in light-emitting devices of different colors (here, blue (B), green (G), and red (R)) are separately formed or separately patterned may be referred to as a side-by-side (SBS) structure. The SBS structure can optimize materials and structures of light-emitting devices and thus can extend the freedom of choices of materials and structures, whereby the luminance and the reliability can be easily improved. In this specification and the like, a light-emitting device capable of emitting white light may be referred to as a white-light-emitting device. Note that a combination of white light-emitting devices with coloring layers (e.g., color filters) enables a full-color display apparatus.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

### Light-Emitting Device

Structures of light-emitting devices can be classified roughly into a single structure and a tandem structure. A light-emitting device having a single structure includes one light-emitting unit between a pair of electrodes. The light-emitting unit includes one or more light-emitting layers. To obtain white light emission with a single structure, two or more light-emitting layers are selected such that emission of the light-emitting layers can produce white color. For example, in the case of two colors, when emission colors of a first light-emitting layer and a second light-emitting layer are complementary colors, the light-emitting device can be configured to emit white light as a whole. To obtain white light emission by using three or more light-emitting layers, the light-emitting device is configured to emit white light as a whole by combining emission colors of the three or more light-emitting layers.

A light-emitting device having a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission with a tandem structure, the light-emitting device is configured to emit white light by combining light from light-emitting layers of a plurality of light-emitting units. Note that a combination of emission colors for obtaining white light emission is similar to that for a single structure. In the light-emitting device with a tandem structure, it is preferable that an intermediate layer such as a charge-generation layer be provided between the plurality of light-emitting units.

When a white-light-emitting device and a light-emitting device with an SBS structure are compared to each other, the latter can have lower power consumption than the former. Meanwhile, the white-light-emitting device is preferable in terms of lower manufacturing cost and higher manufacturing yield because the manufacturing process of the white-light-emitting device is simpler than that of the light-emitting device with the SBS structure.

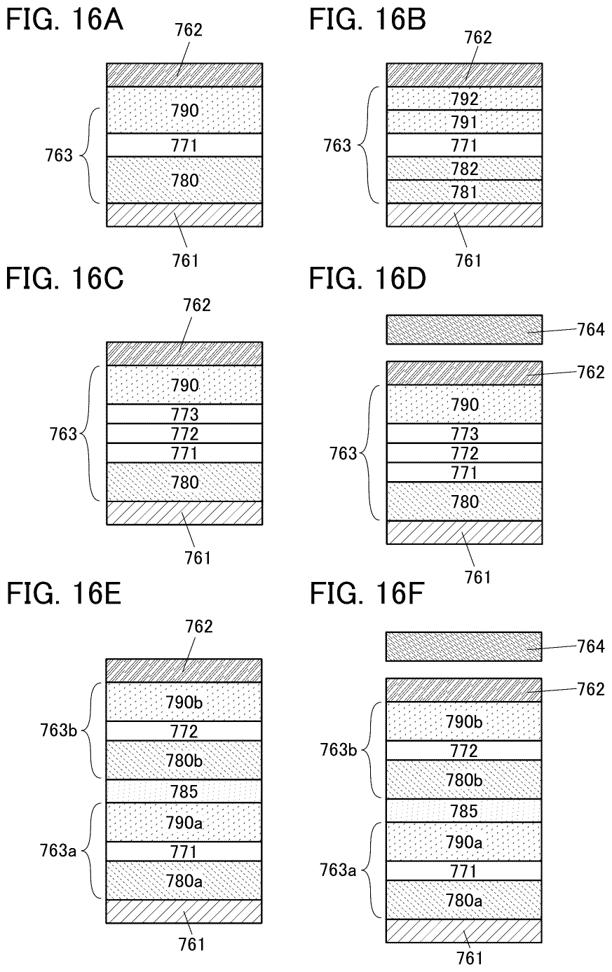

As illustrated in FIG. 16A, the light-emitting device includes an EL layer 763 between a pair of electrodes (a lower electrode 761 and an upper electrode 762). The EL layer 763 can be formed of a plurality of layers such as a layer 780, a light-emitting layer 771, and a layer 790.

The light-emitting layer 771 contains at least a light-emitting substance (also referred to as a light-emitting material).

In the case where the lower electrode 761 is an anode and the upper electrode 762 is a cathode, the layer 780 includes one or more of a layer containing a substance having a high hole-injection property (hole-injection layer), a layer containing a substance having a high hole-transport property (hole-transport layer), and a layer containing a substance having a high electron-blocking property (electron-blocking layer). Furthermore, the layer 790 includes one or more of a layer containing a substance having a high electron-injection property (electron-injection layer), a layer containing a substance having a high electron-transport property (electron-transport layer), and a layer containing a substance having a high hole-blocking property (hole-blocking layer). In the case where the lower electrode 761 is a cathode and the upper electrode 762 is an anode, the structures of the layer 780 and the layer 790 are interchanged.

The structure including the layer 780, the light-emitting layer 771, and the layer 790, which is provided between the pair of electrodes, can function as a single light-emitting unit, and the structure in FIG. 16A is referred to as a single structure in this specification.

FIG. 16B is a modification example of the EL layer 763 included in the light-emitting device illustrated in FIG. 16A. Specifically, the light-emitting device illustrated in FIG. 16B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected into the light-emitting layer 771, and the efficiency of the recombination of carriers in the light-emitting layer 771 can be enhanced.

Note that structures in which a plurality of light-emitting layers (the light-emitting layer 771 and light-emitting layers 772 and 773) are provided between the layer 780 and the layer 790 as illustrated in FIGS. 16C and 16D are variations of a single structure. Although FIGS. 16C and 16D each illustrate an example in which three light-emitting layers are included, the number of light-emitting layers in a light-emitting device with a single structure may be two or four or more.

In addition, the light-emitting device with a single structure may include a buffer layer between two light-emitting layers.

A structure in which a plurality of light-emitting units (a light-emitting unit 763a and a light-emitting unit 763b) are connected in series through a charge-generation layer 785 (also referred to as an intermediate layer) as illustrated in FIGS. 16E and 16F is referred to as a tandem structure in this specification. The tandem structure may be referred to as a stack structure. The tandem structure enables a light-emitting device to emit light with high luminance. Furthermore, the amount of current needed for obtaining a predetermined luminance can be smaller in the tandem structure than in the single structure; thus, the tandem structure enables higher reliability.

Note that FIGS. 16D and 16F each illustrate an example in which the display apparatus includes a layer 764 overlapping with the light-emitting device. FIG. 16D is an example in which the layer 764 overlaps with the light-emitting device illustrated in FIG. 16C, and FIG. 16F illustrates an example in which the layer 764 overlaps with the light-emitting device illustrated in FIG. 16E. In FIGS. 16D and 16F, a conductive film that transmits visible light is used for the upper electrode 762 so that light is extracted from the upper electrode 762 side.

One or both of a color conversion layer and a color filter (coloring layer) can be used as the layer 764.

In FIGS. 16C and 16D, light-emitting substances that emit light of the same color or the same light-emitting substance may be used for the light-emitting layers 771, 772, and 773. For example, a light-emitting substance that emits blue light may be used for the light-emitting layers 771, 772, and 773. In a subpixel that exhibits blue light, blue light from the light-emitting device can be extracted as it is. In a subpixel that exhibits red light and a subpixel that exhibits green light, respective color conversion layers are provided as the layer 764 illustrated in FIG. 16D, whereby blue light emitted by light-emitting devices can be converted into light with a longer wavelength and thus red light or green light can be extracted. As the layer 764, both a color conversion layer and a coloring layer are preferably used. In some cases, part of light emitted from the light-emitting device is transmitted through the color conversion layer without being converted. When light passing through the color conversion layer is extracted through the coloring layer, light other than light of a desired color can be absorbed by the coloring layer, and color purity of light exhibited by a subpixel can be improved.

In FIGS. 16C and 16D, light-emitting substances that emit light of different colors may be used for the light-emitting layers 771, 772, and 773. When the light-emitting layers 771, 772, and 773 emit light of complementary colors, white light emission can be obtained. The light-emitting device with a single structure preferably includes a light-emitting layer containing a light-emitting substance that emits blue light and a light-emitting layer containing a light-emitting substance that emits visible light with a longer wavelength than blue light, for example.

A color filter may be provided as the layer 764 illustrated in FIG. 16D. When white light passes through a color filter, light of a desired color can be obtained.

In the case where the light-emitting device with a single structure includes three light-emitting layers, for example, a light-emitting layer containing a light-emitting substance that emits red (R) light, a light-emitting layer containing a light-emitting substance that emits green (G) light, and a light-emitting layer containing a light-emitting substance that emits blue (B) light are preferably included. The stacking order of the light-emitting layers can be RGB or RBG from an anode side, for example. In that case, a buffer layer may be provided between R and G or between R and B.

In the case where the light-emitting device with a single structure includes two light-emitting layers, for example, a light-emitting layer containing a light-emitting substance that emits blue (B) light and a light-emitting layer containing a light-emitting substance that emits yellow (Y) light are preferably included. Such a structure may be referred to as a BY single structure.

A light-emitting device that emits white light preferably contains two or more kinds of light-emitting substances. In order to obtain white light, two light-emitting substances may be selected such that colors of light emitted by the light-emitting substances are complementary colors, or two or more light-emitting substances may be selected such that colors of light emitted by the light-emitting substances are combined to be white. For example, when two light-emitting layers are used to obtain white light, light-emitting substances may be selected such that the two light-emitting layers emit light of complementary colors. For example, when emission colors of a first light-emitting layer and a second light-emitting layer are complementary colors, the light-emitting device can emit white light as a whole. In the case where three or more light-emitting layers are used to obtain white light emission, the light-emitting device is configured to emit white light as a whole by combining emission colors of the three or more light-emitting layers.

In FIGS. 16C and 16D, the layers 780 and 790 may each have a stacked-layer structure of two or more layers as illustrated in FIG. 16B.

In FIGS. 16E and 16F, light-emitting substances that emit light of the same color, or moreover, the same light-emitting substance may be used for the light-emitting layers 771 and 772. For example, in light-emitting devices included in subpixels that exhibit light of different colors, a light-emitting substance that emits blue light can be used for each of the light-emitting layers 771 and 772. In a subpixel that exhibits blue light, blue light from the light-emitting device can be extracted as it is. In each of the subpixel that exhibits red light and the subpixel that exhibits green light, a color conversion layer is provided as the layer 764 illustrated in FIG. 16F for converting blue light from the light-emitting device into light with a longer wavelength, so that red light or green light can be extracted. As the layer 764, both a color conversion layer and a coloring layer are preferably used.

In FIGS. 16E and 16F, light-emitting substances that emit light of different colors may be used for the light-emitting layers 771 and 772. When the light-emitting layers 771 and 772 emit light of complementary colors, white light emission can be obtained. As the layer 764 illustrated in FIG. 16F, a color filter may be provided. When white light passes through a color filter, light of a desired color can be obtained.

Although FIGS. 16E and 16F each illustrate an example in which the light-emitting unit 763a includes one light-emitting layer 771 and the light-emitting unit 763b includes one light-emitting layer 772, one embodiment of the present invention is not limited thereto. Each of the light-emitting units 763a and 763b may include two or more light-emitting layers.

Although FIGS. 16E and 16F each illustrate an example of a light-emitting device including two light-emitting units, one embodiment of the present invention is not limited thereto. The light-emitting device may include three or more light-emitting units. Note that a structure including two light-emitting units and a structure including three light-emitting units may be referred to as a two-unit tandem structure and a three-unit tandem structure, respectively.

In each of FIGS. 16E and 16F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layers 780a and 780b each include one or more of a hole-injection layer, a hole-transport layer, and an electron-blocking layer. Furthermore, the layers 790a and 790b each include one or more of an electron-injection layer, an electron-transport layer, and a hole-blocking layer. In the case where the lower electrode 761 is a cathode and the upper electrode 762 is an anode, the structures of the layers 780a and 790a are interchanged and the structures of the layers 780b and 790b are interchanged.

In the case where the lower electrode 761 is an anode and the upper electrode 762 is a cathode, the layer 780a includes a hole-injection layer and a hole-transport layer over the hole-injection layer, and may further include an electron-blocking layer over the hole-transport layer, for example. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, the layer 780a includes an electron-injection layer and an electron-transport layer over the electron-injection layer, and may further include a hole-blocking layer over the electron-transport layer, for example. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing the light-emitting device with a tandem structure, two light-emitting units are stacked with the charge-generation layer 785 therebetween. The charge-generation layer 785 has a function of injecting electrons into one of the two light-emitting units and injecting holes into the other when voltage is applied between the pair of electrodes.

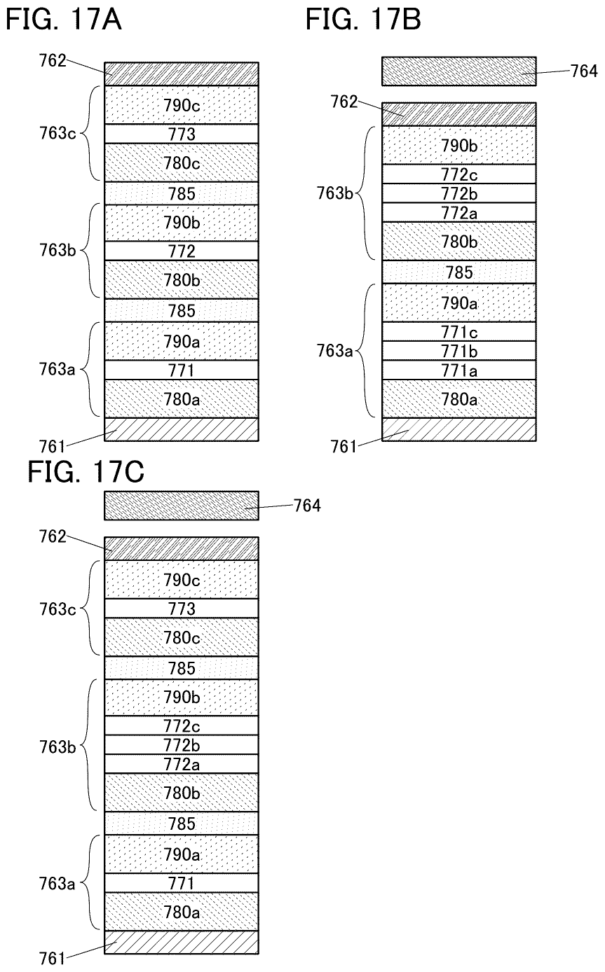

Examples of the light-emitting device with a tandem structure are structures illustrated in FIGS. 17A to 17C.

FIG. 17A illustrates a structure including three light-emitting units. In the structure illustrated in FIG. 17A, a plurality of light-emitting units (the light-emitting units 763a and 763b and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layers 780a and 780b, and the layer 790c can have a structure applicable to the layers 790a and 790b.

In FIG. 17A, the light-emitting layers 771, 772, and 773 can contain light-emitting substances that emit light of the same color. Specifically, the light-emitting layers 771, 772, and 773 can each contain a blue (B) light-emitting substance (i.e., a B/B/B three-unit tandem structure). Note that “b/a” means that a light-emitting unit containing a light-emitting substance that emits light of the color “b” is provided over a light-emitting unit containing a light-emitting substance that emits light of the color “a” with a charge-generation layer therebetween.

In FIG. 17A, light-emitting substances that emit light of different colors may be used for some or all of the light-emitting layers 771, 772, and 773. Examples of the combination of emission colors for the light-emitting layers 771, 772, and 773 include blue (B) for two of them and yellow (Y) for the other; and red (R) for one of them, green (G) for another, and blue (B) for the other.

Note that the structure containing the light-emitting substances that emit light of the same color is not limited to the above structure. For example, a light-emitting device with a tandem structure may be employed in which light-emitting units each including a plurality of light-emitting layers are stacked as illustrated in FIG. 17B. FIG. 17B illustrates a structure in which two light-emitting units (the light-emitting units 763a and 763b) are connected in series through the charge-generation layer 785. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 17B, the light-emitting unit 763a is configured to emit white (W) light by selecting light-emitting substances for the light-emitting layers 771a, 771b, and 771c such that their emission colors are complementary colors. Furthermore, the light-emitting unit 763b is configured to emit white (W) light by selecting light-emitting substances for the light-emitting layers 772a, 772b, and 772c such that their emission colors are complementary colors. That is, the structure illustrated in FIG. 17B is a two-unit tandem structure of W/W. Note that there is no particular limitation on the stacking order of the light-emitting substances having complementary emission colors. The practitioner can select the optimal stacking order as appropriate. Although not illustrated, a W/W/W three-unit tandem structure or a tandem structure with four or more units may be employed.

In the case of a light-emitting device with a tandem structure, any of the following structures may be employed, for example: a B/Y or Y/B two-unit tandem structure including a light-emitting unit that emits yellow (Y) light and a light-emitting unit that emits blue (B) light; a R⋅G/B or B/R⋅G two-unit tandem structure including a light-emitting unit that emits red (R) and green (G) light and a light-emitting unit that emits blue (B) light; a B/Y/B three-unit tandem structure including a light-emitting unit that emits blue (B) light, a light-emitting unit that emits yellow (Y) light, and a light-emitting unit that emits blue (B) light in this order; a B/YG/B three-unit tandem structure including a light-emitting unit that emits blue (B) light, a light-emitting unit that emits yellow-green (YG) light, and a light-emitting unit that emits blue (B) light in this order; and a B/G/B three-unit tandem structure including a light-emitting unit that emits blue (B) light, a light-emitting unit that emits green (G) light, and a light-emitting unit that emits blue (B) light in this order. Note that “a⋅b” means that one light-emitting unit contains a light-emitting substance that emits light of the color “a” and a light-emitting substance that emits light of the color “b”.

As illustrated in FIG. 17C, a light-emitting unit including one light-emitting layer and a light-emitting unit including a plurality of light-emitting layers may be used in combination.

Specifically, in the structure illustrated in FIG. 17C, a plurality of light-emitting units (the light-emitting units 763a, 763b, and 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

The structure illustrated in FIG. 17C can be, for example, a B/R⋅G⋅YG/B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light.

Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from the anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

Next, materials that can be used for the light-emitting device will be described.

A conductive film that transmits visible light is used for the electrode through which light is extracted, which is either the lower electrode 761 or the upper electrode 762. A conductive film that reflects visible light is preferably used for the electrode through which light is not extracted. In the case where the display apparatus includes a light-emitting device that emits infrared light, it is preferable that a conductive film that transmits visible light and infrared light be used for the electrode through which light is extracted, and a conductive film that reflects visible light and infrared light be used for the electrode through which light is not extracted.

A conductive film that transmits visible light may be used also for the electrode through which light is not extracted. In that case, the electrode is preferably provided between a reflective layer and the EL layer 763. In other words, light emitted from the EL layer 763 may be reflected by the reflective layer to be extracted from the display apparatus.

As a material for the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (In—Sn oxide, also referred to as ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium or an alloy of silver, palladium, and copper (Ag—Pd—Cu, also referred to as APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting device preferably employs a microcavity structure. Therefore, one of the pair of electrodes of the light-emitting device is preferably an electrode having properties of transmitting and reflecting visible light (transflective electrode), and the other is preferably an electrode having a property of reflecting visible light (reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting device. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least a light-emitting layer. In addition to the light-emitting layer, the light-emitting device may further include a layer containing any of a substance having a high hole-injection property, a substance having a high hole-transport property, a hole-blocking material, a substance having a high electron-transport property, an electron-blocking material, a substance having a high electron-injection property, a substance having a bipolar property (a substance with high electron-and hole-transport properties), and the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used in the light-emitting device, and an inorganic compound may also be included. Each layer included in the light-emitting device can be formed by any of the following methods: an evaporation method (including a vacuum evaporation method), a transfer method, a printing method, an inkjet method, a coating method, and the like.

The light-emitting layer contains one or more kinds of light-emitting substances. As the light-emitting substance, a substance whose emission color is blue, violet, bluish violet, green, yellowish green, yellow, orange, red, or the like is appropriately used. As the light-emitting substance, a substance that emits near-infrared light can also be used.

Examples of the light-emitting substance include a fluorescent material, a phosphorescent material, a TADF material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the hole-transport material, it is possible to use a material with a high hole-transport property which can be used for the hole-transport layer and will be described later. As the electron-transport material, it is possible to use a material with a high electron-transport property which can be used for the electron-transport layer and will be described later. Alternatively, as one or more kinds of organic compounds, a bipolar material or a TADF material may be used.

The light-emitting layer preferably contains a phosphorescent material and a combination of a hole-transport material and an electron-transport material that easily forms an exciplex, for example. With such a structure, light emission can be efficiently obtained by exciplex-triplet energy transfer (ExTET), which is energy transfer from the exciplex to the light-emitting substance (the phosphorescent material). When a combination of materials is selected so as to form an exciplex that emits light whose wavelength overlaps with the wavelength of a lowest-energy-side absorption band of the light-emitting substance, energy can be transferred smoothly and light emission can be obtained efficiently. With the above structure, high efficiency, low-voltage driving, and a long lifetime of a light-emitting device can be achieved at the same time.

A hole-injection layer injects holes from an anode to a hole-transport layer and contains a material with a high hole-injection property. Examples of the material with a high hole-injection property include an aromatic amine compound and a composite material containing a hole-transport material and an acceptor material (electron-accepting material).

As the hole-transport material, it is possible to use a material with a high hole-transport property which can be used for the hole-transport layer and will be described later.

As the acceptor material, for example, an oxide of a metal belonging to any of Group 4 to Group 8 of the periodic table can be used. Specific examples include molybdenum oxide, vanadium oxide, niobium oxide, tantalum oxide, chromium oxide, tungsten oxide, manganese oxide, and rhenium oxide. Among these, molybdenum oxide is especially preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to Group4 to Group 8 of the periodic table (typified by molybdenum oxide) may be used, for example.

The hole-transport layer transports holes, which are injected from the anode by the hole-injection layer, to the light-emitting layer. The hole-transport layer contains a hole-transport material. The hole-transport material preferably has a hole mobility higher than or equal to 1×10⁻⁶ cm²/Vs. Note that other substances can also be used as long as the substances have a hole-transport property higher than an electron-transport property. The hole-transport material is preferably a material with a high hole-transport property, such as a π-electron rich heteroaromatic compound (e.g., a carbazole derivative, a thiophene derivative, and a furan derivative) or an aromatic amine (a compound having an aromatic amine skeleton).

The electron-blocking layer is provided in contact with the light-emitting layer. The electron-blocking layer has a hole-transport property and contains a material that can block an electron. Among the above-described hole-transport materials, a material with an electron-blocking property can be used for the electron-blocking layer.

Since the electron-blocking layer has a hole-transport property, the electron-blocking layer can also be referred to as a hole-transport layer. A hole-transport layer with an electron-blocking property can be referred to as an electron-blocking layer.

The electron-transport layer transports electrons, which are injected from the cathode by the electron-injection layer, to the light-emitting layer. The electron-transport layer contains an electron-transport material. The electron-transport material preferably has an electron mobility higher than or equal to 1×10⁻¹ cm²/Vs. Note that other substances can also be used as long as the substances have an electron-transport property higher than a hole-transport property. The electron-transport material can be a material with a high electron-transport property, e.g., a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, and a π-electron deficient heteroaromatic compound such as a nitrogen-containing heteroaromatic compound.

The hole-blocking layer is provided in contact with the light-emitting layer. The hole-blocking layer has an electron-transport property and contains a material that can block a hole. Among the above-described electron-transport materials, a material with a hole-blocking property can be used for the hole-blocking layer.

Since the hole-blocking layer has an electron-transport property, the hole-blocking layer can also be referred to as an electron-transport layer. An electron-transport layer with a hole-blocking property can be referred to as a hole-blocking layer.

An electron-injection layer injects electrons from a cathode to an electron-transport layer and contains a material with a high electron-injection property. As the material with a high electron-injection property, an alkali metal, an alkaline earth metal, or a compound thereof can be used. As the material with a high electron-injection property, a composite material containing an electron-transport material and a donor material (electron-donating material) can also be used.

The lowest unoccupied molecular orbital (LUMO) level of the material with a high electron-injection property preferably has a small difference (specifically, 0.5 eV or less) from the work function of a material for the cathode.

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where x is a given number), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOₓ), or cesium carbonate, for example. The electron-injection layer may have a stacked-layer structure of two or more layers. An example of the stacked-layer structure is a structure in which lithium fluoride is used for the first layer and ytterbium is used for the second layer.

The electron-injection layer may contain an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the LUMO level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by cyclic voltammetry (CV), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), 2,2′-(1,3-phenylene)bis(9-phenyl-1,10-phenanthroline) (abbreviation: mPPhen2P), diquinoxalino[2,3-α:2′,3′-c]phenazine (abbreviation: HATNA), 2,4,6-tris[3′-(pyridin-3-yl)biphenyl-3-yl]-1,3,5-triazine (abbreviation: TmPPPyTz), or the like can be used as the organic compound having an unshared electron pair. Note that NBPhen has a higher glass transition temperature (T_{g}) than BPhen and thus has high heat resistance.

The charge-generation layer preferably includes a p-type layer. The p-type layer preferably contains an acceptor material. For example, the p-type layer preferably contains the above-described hole-transport material and acceptor material that can be used for the hole-injection layer.

The charge-generation layer preferably includes a layer containing a material with a high electron-injection property. The layer can also be referred to as an electron-injection buffer layer or an n-type layer. The electron-injection buffer layer is preferably provided between the p-type layer and the electron-transport layer. With use of the electron-injection buffer layer, an injection barrier between the p-type layer and the electron-transport layer can be lowered; thus, electrons generated in the p-type layer can be easily injected into the electron-transport layer.

The electron-injection buffer layer preferably contains an alkali metal or an alkaline earth metal, and can contain an alkali metal compound or an alkaline earth metal compound, for example. Specifically, the electron-injection buffer layer preferably contains an inorganic compound containing an alkali metal and oxygen or an inorganic compound containing an alkaline earth metal and oxygen, and further preferably contains an inorganic compound containing lithium and oxygen (e.g., lithium oxide (Li₂O)). Alternatively, the above-described material that can be used for the electron-injection layer can be favorably used for the electron-injection buffer layer.

The charge-generation layer preferably includes a layer containing a material with a high electron-transport property. The layer can also be referred to as an electron-relay layer. The electron-relay layer is preferably provided between the p-type layer and the electron-injection buffer layer. In the case where the charge-generation layer does not include an electron-injection buffer layer, the electron-relay layer is preferably provided between the p-type layer and the electron-transport layer. The electron-relay layer has a function of preventing an interaction between the p-type layer and the electron-injection buffer layer (or the electron-transport layer) and transferring electrons smoothly.

For the electron-relay layer, a phthalocyanine-based material such as copper(II) phthalocyanine (abbreviation: CuPc), or a metal complex having a metal-oxygen bond and an aromatic ligand is preferably used.

Note that the p-type layer, the electron-injection buffer layer, and the electron-relay layer cannot be clearly distinguished from one another on the basis of the cross-sectional shape or properties in some cases.

When the charge-generation layer is provided between two light-emitting units to be stacked, an increase in driving voltage can be inhibited.

At least part of this embodiment can be implemented as appropriate in combination with any of the other embodiments described in this specification.

### Embodiment 5

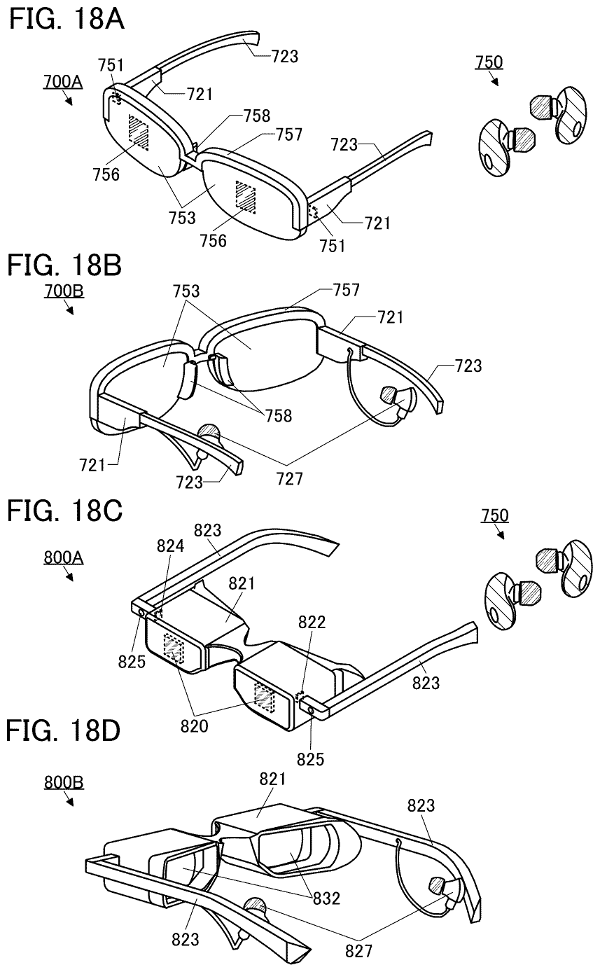

In this embodiment, electronic appliances of one embodiment of the present invention will be described with reference to FIGS. 18A to 18D, FIGS. 19A to 19F, FIGS. 20A to 20G, and FIGS. 21A to 21C.

Electronic appliances in this embodiment each include the display panel (display apparatus) of one embodiment of the present invention in a display portion. The display panel of one embodiment of the present invention can be easily increased in resolution and definition and can achieve high display quality. Thus, the display panel of one embodiment of the present invention can be used for display portions of a variety of electronic appliances.

Examples of the electronic appliances include a digital camera, a digital video camera, a digital photo frame, a mobile phone, a portable game console, a portable information terminal, and an audio reproducing device, in addition to electronic appliances with a relatively large screen, such as a television apparatus, desktop and laptop personal computers, a monitor of a computer and the like, digital signage, and a large game machine like a pachinko machine.

In particular, the display panel of one embodiment of the present invention can have high resolution, and thus can be favorably used for an electronic appliance having a relatively small display portion. Examples of such an electronic appliance include watch-type and bracelet-type information terminals (wearable devices) and wearable devices capable of being worn on a head, such as a VR device like a head-mounted display, a glasses-type AR device, and a mixed reality (MR) device.

The definition of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display panel having one or both of such high definition and high resolution can further increase realistic sensation, sense of depth, and the like. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic appliance in this embodiment may include a sensor (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays).

The electronic appliance in this embodiment can have a variety of functions. For example, the electronic appliance can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices capable of being worn on a head are described with reference to FIGS. 18A to 18D. The wearable devices have one or both of a function of displaying AR content and a function of displaying VR content. Note that these wearable devices may have a function of displaying substitutional reality (SR) or MR content, in addition to AR and VR content. The electronic appliance having a function of displaying content of at least one of AR, VR, SR, MR, and the like enables the user to feel a higher level of immersion.

An electronic appliance 700A illustrated in FIG. 18A and an electronic appliance 700B illustrated in FIG. 18B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used for the display panels 751. Thus, the electronic appliances are capable of performing ultrahigh-resolution display.

The electronic appliances 700A and 700B can each project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic appliances 700A and 700B are capable of AR display.

In the electronic appliances 700A and 700B, a camera capable of capturing images of the front side may be provided as the image capturing portion. Furthermore, when the electronic appliances 700A and 700B are provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic appliances 700A and 700B are provided with a battery, so that they can be charged wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

Various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic appliance 800A illustrated in FIG. 18C and an electronic appliance 800B illustrated in FIG. 18D each include a pair of display portions 820, a housing 821, a communication portion 822, a pair of wearing portions 823, a control portion 824, a pair of image capturing portions 825, and a pair of lenses 832.

The display panel of one embodiment of the present invention can be used in the display portions 820. Thus, the electronic appliances are capable of performing ultrahigh-resolution display. Such electronic appliances provide a high sense of immersion to the user.

The display portions 820 are positioned inside the housing 821 so as to be seen through the lenses 832. When the pair of display portions 820 display different images, three-dimensional display using parallax can be performed.

The electronic appliances 800A and 800B can be regarded as electronic appliances for VR. The user who wears the electronic appliance 800A or the electronic appliance 800B can see images displayed on the display portions 820 through the lenses 832.

The electronic appliances 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic appliances 800A and 800B preferably include a mechanism for adjusting focus by changing the distance between the lenses 832 and the display portions 820.

The electronic appliance 800A or the electronic appliance 800B can be mounted on the user's head with the wearing portions 823. FIG. 18C and the like illustrate examples where the wearing portion 823 has a shape like a temple of glasses; however, one embodiment of the present invention is not limited thereto. The wearing portion 823 can have any shape with which the user can wear the electronic appliance, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance to an object may be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic appliance 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic appliance 800A.

The electronic appliances 800A and 800B may each include an input terminal. To the input terminal, a cable for supplying a video signal from a video output device or the like, power for charging a battery provided in the electronic appliance, and the like can be connected.

The electronic appliance of one embodiment of the present invention may have a function of performing wireless communication with earphones 750. The earphones 750 include a communication portion (not illustrated) and have a wireless communication function. The earphones 750 can receive information (e.g., audio data) from the electronic appliance with the wireless communication function. For example, the electronic appliance 700A in FIG. 18A has a function of transmitting information to the earphones 750 with the wireless communication function. As another example, the electronic appliance 800A in FIG. 18C has a function of transmitting information to the earphones 750 with the wireless communication function.

The electronic appliance may include an earphone portion. The electronic appliance 700B illustrated in FIG. 18B includes earphone portions 727. For example, the earphone portion 727 can be connected to the control portion by wire. Part of a wiring that connects the earphone portion 727 and the control portion may be positioned inside the housing 721 or the wearing portion 723.

Similarly, the electronic appliance 800B illustrated in FIG. 18D includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic appliance may include an audio output terminal to which earphones, headphones, or the like can be connected. The electronic appliance may include one or both of an audio input terminal and an audio input mechanism. As the audio input mechanism, a sound collecting device such as a microphone can be used, for example. The electronic appliance may have a function of a headset by including the audio input mechanism.

As described above, both the glasses-type device (e.g., the electronic appliances 700A and 700B) and the goggles-type device (e.g., the electronic appliances 800A and 800B) are preferable as the electronic appliance of one embodiment of the present invention.

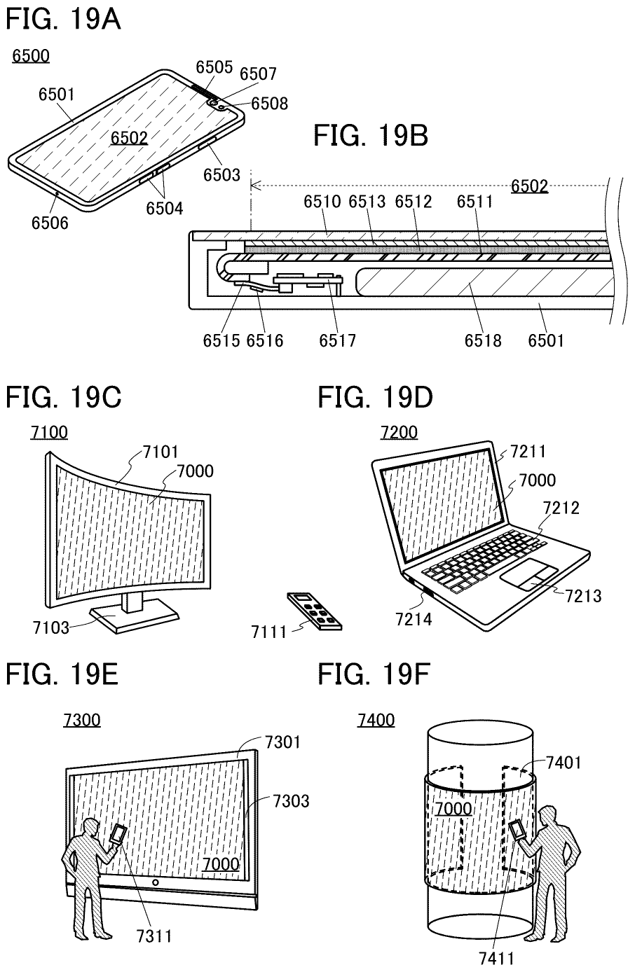

An electronic appliance 6500 illustrated in FIG. 19A is a portable information terminal that can be used as a smartphone.

The electronic appliance 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used in the display portion 6502.

FIG. 19B is a schematic cross-sectional view including an end portion of the housing 6501 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display apparatus of one embodiment of the present invention can be used as the display panel 6511. Thus, an extremely lightweight electronic appliance can be obtained. Since the display panel 6511 is extremely thin, the battery 6518 with high capacity can be mounted without an increase in the thickness of the electronic appliance. Moreover, part of the display panel 6511 is folded back so that a connection portion with the FPC 6515 is provided on the back side of the pixel portion, whereby an electronic appliance with a narrow bezel can be obtained.

FIG. 19C illustrates an example of a television apparatus. In a television apparatus 7100, a display portion 7000 is incorporated in a housing 7101. Here, the housing 7101 is supported by a stand 7103.

Operation of the television apparatus 7100 illustrated in FIG. 19C can be performed with an operation switch provided in the housing 7101 and a separate remote control 7111. Alternatively, the display portion 7000 may include a touch sensor, and the television apparatus 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be controlled.

Note that the television apparatus 7100 includes a receiver, a modem, and the like. A general television broadcast can be received with the receiver. When the television apparatus is connected to a communication network by wire or wirelessly via the modem, one-way (from a transmitter to a receiver) or two-way (between a transmitter and a receiver or between receivers, for example) information communication can be performed.

FIG. 19D illustrates an example of a laptop personal computer. A laptop personal computer 7200 includes a housing 7211, a keyboard 7212, a pointing device 7213, an external connection port 7214, and the like. The display portion 7000 is incorporated in the housing 7211.

FIGS. 19E and 19F illustrate examples of digital signage.

Digital signage 7300 illustrated in FIG. 19E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 19F illustrates digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 19E and 19F, it is preferable that the digital signage 7300 or the digital signage 7400 can work with an information terminal 7311 or an information terminal 7411, such as a smartphone that a user has, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The display panel of one embodiment of the present invention can be used in the display portion 7000 illustrated in each of FIGS. 19C to 19F.

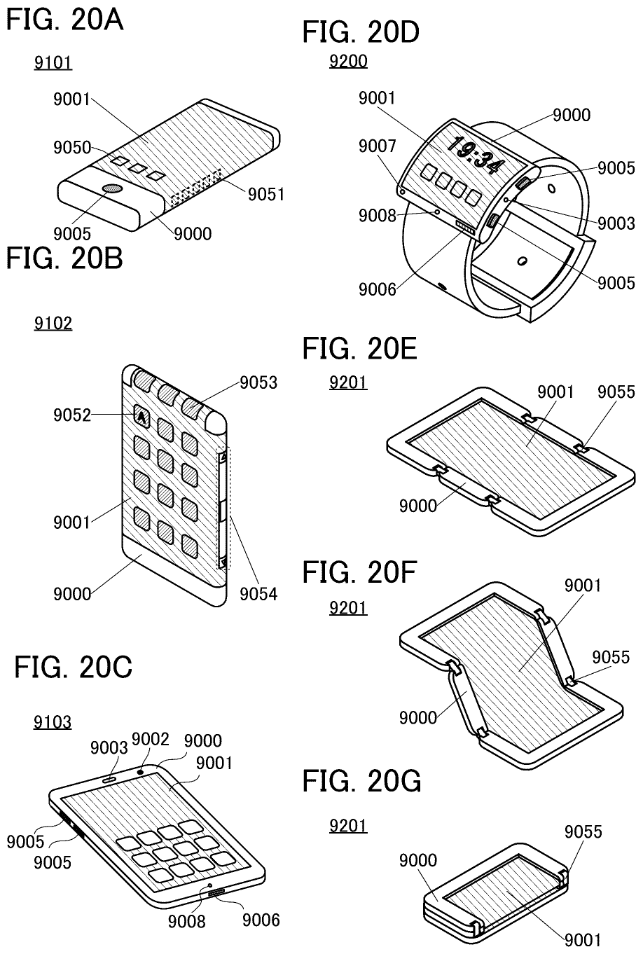

Electronic appliances illustrated in FIGS. 20A to 20G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, chemical substance, sound, time, hardness, electric field, current, voltage, electric power, radiation, flow rate, humidity, gradient, oscillation, odor, or infrared rays), a microphone 9008, and the like.

The electronic appliances illustrated in FIGS. 20A to 20G have a variety of functions. For example, the electronic appliances can have a function of displaying a variety of information (e.g., a still image, a moving image, and a text image) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic appliances are not limited thereto, and the electronic appliances can have a variety of functions. The electronic appliances may include a plurality of display portions. The electronic appliances may be provided with a camera or the like and have a function of capturing a still image or a moving image and storing the captured image in a storage medium (an external storage medium or a storage medium incorporated in the camera), a function of displaying the captured image on the display portion, and the like.

The electronic appliances illustrated in FIGS. 20A to 20G are described in detail below.

FIG. 20A is a perspective view of a portable information terminal 9101. The portable information terminal 9101 can be used as a smartphone, for example. The portable information terminal 9101 may include the speaker 9003, the connection terminal 9006, the sensor 9007, and the like. The portable information terminal 9101 can display text and image information on its plurality of surfaces. FIG. 20A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 20B is a perspective view of a portable information terminal 9102. The portable information terminal 9102 has a function of displaying information on three or more surfaces of the display portion 9001. In the example illustrated here, information 9052, information 9053, and information 9054 are displayed on different surfaces. For example, the user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 20C is a perspective view of a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 20D is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With the connection terminal 9006, the portable information terminal 9200 can perform mutual data transmission with another information terminal and charging. Note that the charging operation may be performed by wireless power feeding.

FIGS. 20E to 20G are perspective views of a foldable portable information terminal 9201. FIG. 20E is a perspective view illustrating the portable information terminal 9201 that is opened. FIG. 20G is a perspective view illustrating the portable information terminal 9201 that is folded. FIG. 20F is a perspective view illustrating the portable information terminal 9201 that is shifted from one of the states in FIGS. 20E and 20G to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

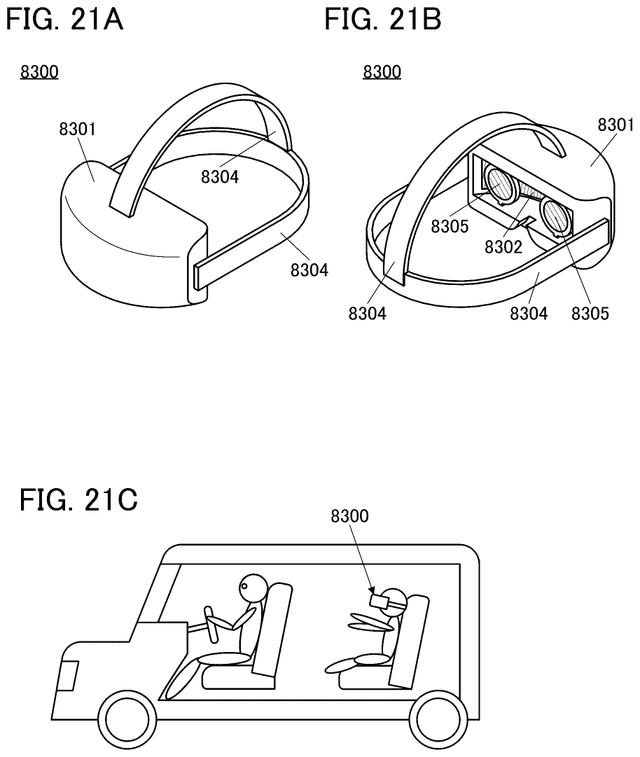

FIG. 21A and FIG. 21B are external views of a head-mounted display 8300. The head-mounted display 8300 includes a housing 8301, a display portion 8302, a band-like fixing member 8304, and a pair of lenses 8305.

A user can see display on the display portion 8302 through the lenses 8305. The display portion 8302 is preferably curved because the user can feel a high realistic sensation. When another image displayed in another region of the display portion 8302 is viewed through the lenses 8305, three-dimensional display using parallax or the like can be performed. Note that the number of the display portions 8302 is not limited to one; two display portions 8302 may be provided for user's respective eyes.

The display apparatus of one embodiment of the present invention can be used for the display portion 8302. The display apparatus of one embodiment of the present invention can have an extremely high resolution. Thus, a pixel is not easily seen by the user even when the user sees display that is magnified by the use of the lenses 8305. In other words, an image with a strong sense of reality can be seen by the user with use of the display portion 8302.

The head-mounted display 8300 preferably has a head tracking function and an eye tracking function. Accordingly, an image displayed can be moved in accordance with the movement of the user and the line of sight of the user. Thus, a highly immersive image can be provided to the user. For example, as illustrated in FIG. 21C, a passenger in the rear seat of a car can wear the head-mounted display 8300. In that case, moving an image in synchronization with the shaking of the car body and not fixing the line of sight, for example, can reduce car sickness as compared with the case where the passenger sees an image with a smartphone, a tablet terminal, or the like.

At least part of this embodiment can be implemented as appropriate in combination with any of the other embodiments described in this specification.

This application is based on Japanese Patent Application Serial No. 2025-009347 filed with Japan Patent Office on Jan. 22, 2025, the entire contents of which are hereby incorporated by reference.

What is claimed is:

1. A display apparatus comprising:
a pixel electrode;
an EL layer;
an upper electrode;
a first insulating layer;
a partition;
a color filter; and
a transistor,
wherein the transistor is positioned below the pixel electrode and is connected to the pixel electrode,
wherein the first insulating layer comprises an end portion over the pixel electrode,
wherein the partition is positioned over the first insulating layer,
wherein the EL layer comprises a light-emitting compound and is in contact with a top surface of the pixel electrode and a top surface of the first insulating layer,
wherein the upper electrode covers a top surface and an end portion of the EL layer and is in contact with the top surface of the first insulating layer and a side surface of the partition,
wherein the color filter is positioned above the upper electrode and the partition and comprises an end portion overlapping with the partition,
wherein the partition has conductivity and an inverse tapered shape in a cross-sectional view, and
wherein a gap is between the partition and the end portion of the first insulating layer.

2. A display apparatus comprising:
a first pixel electrode;
a second pixel electrode;
a first EL layer;
a second EL layer;
a first upper electrode;
a second upper electrode;
a first insulating layer;
a partition;
a first color filter;
a second color filter; and
a transistor,
wherein the transistor is positioned below the first pixel electrode and is connected to the first pixel electrode,
wherein the first insulating layer comprises end portions over the first pixel electrode and the second pixel electrode,
wherein the partition is positioned over the first insulating layer,
wherein the first EL layer comprises a first light-emitting compound and is in contact with a top surface of the first pixel electrode and a top surface of the first insulating layer,
wherein the second EL layer comprises a second light-emitting compound and is in contact with a top surface of the second pixel electrode and the top surface of the first insulating layer,
wherein the first upper electrode covers a top surface and an end portion of the first EL layer and is in contact with a part of the top surface of the first insulating layer and a part of a side surface of the partition,
wherein the second upper electrode covers a top surface and an end portion of the second EL layer and is in contact with another part of the top surface of the first insulating layer and another part of the side surface of the partition,
wherein the first color filter is positioned above the first upper electrode and the partition and comprises an end portion overlapping with the partition,
wherein the second color filter is positioned above the second upper electrode and the partition and comprises an end portion overlapping with the partition,
wherein the partition has conductivity and an inverse tapered shape in a cross-sectional view, and
wherein a gap is between the partition and the end portion of the first insulating layer over the first pixel electrode.

3. The display apparatus according to claim 1,
wherein the EL layer is configured to emit white light, and
wherein the color filter comprises a metal, a pigment, or a dye.

4. The display apparatus according to claim 1,
wherein the EL layer is configured to emit blue light or light having a shorter wavelength than the blue light,
wherein a wavelength conversion layer is provided instead of the color filter, and
wherein the wavelength conversion layer comprises a quantum dot or a fluorescent material.

5. The display apparatus according to claim 1,
wherein an angle between the side surface of the partition and a contact surface of the partition with the first insulating layer is greater than or equal to 95° and less than or equal to 150°.

6. The display apparatus according to claim 1,
wherein the partition comprises indium.

7. The display apparatus according to claim 1,
wherein the transistor comprises a metal oxide in a semiconductor layer where a channel is formed.

8. The display apparatus according to claim 2,
wherein an angle between the side surface of the partition and a contact surface of the partition with the first insulating layer is greater than or equal to 9520 and less than or equal to 150°.

9. The display apparatus according to claim 2, wherein the partition comprises indium.

10. The display apparatus according to claim 2,
wherein the transistor comprises a metal oxide in a semiconductor layer where a channel is formed.
